(19) United States
(12) Patent Application Publication
(10) Pub. No.: US 2026/0314202 A1
(43) Pub. Date: Oct. 8, 2026

(54) DISPLAY DEVICE AND ELECTRONIC DEVICE COMPRISING THE SAME

(71) Applicant: Samsung Display Co., Ltd., Yongin-si (KR)

(72) Inventors: Go Een JEONG, Yongin-si (KR); Hyang A PARK, Yongin-si (KR); Gun Hee KIM, Yongin-si (KR); Kwang Soo BAE, Yongin-si (KR); Seung Jun LEE, Yongin-si (KR); Tae Young CHOI, Yongin-si (KR)

(21) Appl. No.: 19/578,504

(22) Filed: Mar. 25, 2026

(30) Foreign Application Priority Data
Apr. 7, 2025 (KR) 10-2025-0044646

(51) Int. Cl. H10K 59/131; H10D 86/40; H10D 86/60; H10K 59/121

(52) U.S. Cl. CPC H10K 59/131; H10D 86/441; H10D 86/60; H10K 59/1213; H10K 59/1216

(57) ABSTRACT

A display device includes: a first transistor including a first electrode, a second electrode, a first channel portion between the first electrode and the second electrode, a gate electrode overlapping the first channel portion, and a back gate electrode overlapping the first channel portion; a light emitting element; a fifth transistor including a first electrode, a second electrode, and a fifth channel portion between the first electrode and the second electrode; a first driving voltage line transmitting a first driving voltage; and a third driving voltage line transmitting a third driving voltage, wherein the first electrode of the fifth transistor is electrically connected to the second electrode of the first transistor, the first driving voltage line is electrically connected to the second electrode of the fifth transistor, a second driving voltage is transmitted to a cathode, and the third driving voltage line is electrically connected to the back gate electrode.

### CROSS-REFERENCE TO RELATED APPLICATION

The present application claims priority to and the benefit of Korean Patent Application No. 10-2025-0044646, filed on Apr. 7, 2025, in the Korean Intellectual Property Office, the entire disclosure of which is incorporated herein by reference.

### BACKGROUND

### 1. Field

Aspects of some embodiments of the present disclosure relate to a display device and an electronic device comprising the same.

### 2. Description of the Related Art

Electroluminescence displays may be divided into inorganic light emitting display devices and organic light emitting display devices depending on materials of light emitting layers. An active matrix type of organic light emitting display device includes organic light emitting diodes (hereinafter referred to as “OLEDs”) that emit light by themselves, and may have characteristics such as a relatively fast response speed, relatively high light emitting efficiency, relatively high luminance, and a relative desirable viewing angle. In the organic light emitting display device, the OLED is formed in each of pixels. The organic light emitting display device may not only have a fast response speed and excellent light emitting efficiency, luminance, and viewing angle, but may also express a black grayscale as complete black, and thus, may have relatively excellent contrast ratio and color reproducibility.

The above information disclosed in this Background section is only for enhancement of understanding of the background and therefore the information discussed in this Background section does not necessarily constitute prior art.

### SUMMARY

Aspects of some embodiments of the present disclosure include a display device whose display quality may be relatively improved.

However, aspects of some embodiments of the present disclosure are not restricted to those set forth herein. The above and other aspects of embodiments according to the present disclosure will become more apparent to one of ordinary skill in the art to which the present disclosure pertains by referencing the detailed description of the present disclosure given below.

According to some embodiments of the present disclosure, a display device may include: a first transistor including a first electrode, a second electrode, a first channel portion located between the first electrode and the second electrode, a gate electrode overlapping the first channel portion, and a back gate electrode overlapping the first channel portion; a light emitting element including an anode electrode, a cathode electrode, and a light emitting layer located between the anode electrode and the cathode electrode; a fifth transistor including a first electrode, a second electrode, and a fifth channel portion located between the first electrode and the second electrode; a first driving voltage line transmitting a first driving voltage; and a third driving voltage line transmitting a third driving voltage, wherein the first electrode of the fifth transistor is electrically connected to the second electrode of the first transistor, the first driving voltage line is electrically connected to the second electrode of the fifth transistor, a second driving voltage is transmitted to the cathode electrode, and the third driving voltage line is electrically connected to the back gate electrode.

According to some embodiments of the present disclosure, the first driving voltage, the second driving voltage, and the third driving voltage may be constant voltages.

According to some embodiments of the present disclosure, the display device may further include: a first group capacitor located between the first electrode of the first transistor and the gate electrode of the first transistor; and a second group capacitor located between the first electrode of the first transistor and the third driving voltage line.

According to some embodiments of the present disclosure, the first group capacitor may include a first capacitor, a second capacitor, and a third capacitor, the second group capacitor may include a fourth capacitor and a fifth capacitor, and each of the first capacitor, the second capacitor, the third capacitor, the fourth capacitor, and the fifth capacitor may include a first electrode and a second electrode.

According to some embodiments of the present disclosure, the first electrode of the fourth capacitor may be the same as the first electrode of the fifth capacitor.

According to some embodiments of the present disclosure, the first electrode of the fifth capacitor may be located on the second electrode of the fifth capacitor, and the second electrode of the fourth capacitor may be located on the first electrode of the fourth capacitor.

According to some embodiments of the present disclosure, the second electrode of the fourth capacitor may be the same as the back gate electrode, and the first electrode of the first transistor and the second electrode of the first transistor may be located on the second electrode of the fourth capacitor.

According to some embodiments of the present disclosure, the third driving voltage line may be located on the gate electrode of the first transistor.

According to some embodiments of the present disclosure, the third driving voltage line may be electrically connected to the second electrode of the fifth capacitor through a first contact hole, and the third driving voltage line may be electrically connected to the second electrode of the fourth capacitor through a second contact hole.

According to some embodiments of the present disclosure, the first electrode of the first transistor may be electrically connected to a first connection electrode through a fourth contact hole, the first connection electrode may be electrically connected to the first electrode of the fourth capacitor through a third contact hole, and the first connection electrode may be located at a same layer as the third driving voltage line.

According to some embodiments of the present disclosure, the first electrode of the fourth capacitor may be the same as the first electrode of the second capacitor, and the first electrode of the second capacitor may be the same as the first electrode of the third capacitor.

According to some embodiments of the present disclosure, the second electrode of the first capacitor may be the same as the second electrode of the second capacitor.

According to some embodiments of the present disclosure, the first electrode of the first capacitor may be located on the second electrode of the first capacitor, and the first electrode of the first capacitor may be located at a same layer as the first electrode of the first transistor and the second electrode of the first transistor.

According to some embodiments of the present disclosure, the second electrode of the second capacitor may be located on the first electrode of the second capacitor, and the first electrode of the third capacitor may be located on the second electrode of the third capacitor.

According to some embodiments of the present disclosure, the gate electrode of the first transistor may be electrically connected to a second connection electrode through a fifth contact hole, and the second connection electrode may be electrically connected to the second electrode of the third capacitor through a sixth contact hole.

According to some embodiments of the present disclosure, the second electrode of the third capacitor may be electrically connected to a third connection electrode through an eighth contact hole, and the third connection electrode may be electrically connected to the second electrode of the first capacitor through a seventh contact hole.

According to some embodiments of the present disclosure, an electronic device may include: a processor providing an image signal and a control signal including a maximum brightness value; a display module receiving the image signal and the control signal from the processor and displaying an image; and a power module supplying power to the display module, wherein the display module includes: a first transistor including a first electrode, a second electrode, a first channel portion located between the first electrode and the second electrode, a gate electrode overlapping the first channel portion, and a back gate electrode overlapping the first channel portion; a light emitting element including an anode electrode, a cathode electrode, and a light emitting layer located between the anode electrode and the cathode electrode; a fifth transistor including a first electrode, a second electrode, and a fifth channel portion located between the first electrode and the second electrode; a first driving voltage line transmitting a first driving voltage; and a third driving voltage line transmitting a third driving voltage, the first electrode of the fifth transistor is electrically connected to the second electrode of the first transistor, the first driving voltage line is electrically connected to the second electrode of the fifth transistor, a second driving voltage is transmitted to the cathode electrode, the third driving voltage line is electrically connected to the back gate electrode, and the third driving voltage is changed depending on the maximum brightness value.

According to some embodiments of the present disclosure, the third driving voltage may increase as the maximum brightness value decreases.

According to some embodiments of the present disclosure, in a driving current curve of the first transistor, a change amount in driving current may increase as the third driving voltage increases.

According to some embodiments of the present disclosure, the first driving voltage, the second driving voltage, and the third driving voltage may be constant voltages. According to some embodiments, when a first transistor includes an oxide semiconductor, display quality may be relatively improved due to improvement of uniformity, but a gradient of a driving current curve may become gradual at a low luminance and/or a low grayscale. According to some embodiments of the present disclosure, a third driving voltage applied as a back gate voltage to a first transistor in a low-grayscale region is a constant voltage, but may be variably applied according to a brightness value in order to relatively improve luminance sensitivity in the low-grayscale region. Accordingly, display quality of a display device may be relatively improved.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating an electronic device according to some embodiments of the present disclosure;

FIG. 2 is an exploded perspective view of the electronic device according to some embodiments of the present disclosure;

FIG. 3 is a plan view illustrating a display device of FIG. 2;

FIG. 4 is a cross-sectional view taken along line A-A′ of FIG. 3;

FIG. 5 is a plan view illustrating portion B of FIG. 3;

FIG. 6 is a block diagram illustrating the display device of FIG. 2;

FIG. 7 is an equivalent circuit diagram illustrating a pixel circuit according to some embodiments of the present disclosure;

FIG. 8 is a modified circuit diagram illustrating portion K of FIG. 7 in more detail;

FIG. 9 is a schematic cross-sectional view illustrating a connection relationship between a pixel circuit and a light emitting element according to some embodiments of the present disclosure;

FIG. 10 is a plan view illustrating a first semiconductor layer located in the display device according to some embodiments of the present disclosure;

FIG. 11 is a plan view further illustrating a first gate metal layer located in the display device according to some embodiments of the present disclosure;

FIG. 12 is a plan view further illustrating a second gate metal layer located in the display device according to some embodiments of the present disclosure;

FIG. 13 is a plan view further illustrating a second semiconductor layer located in the display device according to some embodiments of the present disclosure;

FIG. 14 is a plan view further illustrating a third gate metal layer located in the display device according to some embodiments of the present disclosure;

FIG. 15 is a cross-sectional view illustrating the display device according to some embodiments of the present disclosure;

FIG. 16 is graphs illustrating a driving current curve of a first transistor according to some embodiments of the present disclosure;

FIG. 17 is a table for describing the display device according to some embodiments of the present disclosure;

FIG. 18 is a block diagram of an electronic device according to some embodiments of the present disclosure; and

FIG. 19 is schematic views of electronic devices according to some embodiments of the present disclosure.

### DETAILED DESCRIPTION

The advantages and features of the embodiments disclosed herein, and methods of achieving them, will become apparent upon reference to the embodiments described in more detail with accompanying drawings. However, the invention according to the present disclosure is not limited to the embodiments disclosed herein, but will be embodied in many different forms, and these embodiments are provided merely to make the disclosure complete and to fully inform one of ordinary skill in the art to which the invention according to the present disclosure belongs, and the invention according to the present disclosure is defined by the scope of the claims.

References to an element or layer as being “on” another element or layer include both cases in which another layer or element is directly on top of or interposed between other elements. Throughout this specification, like reference numerals refer to like components. The shapes, sizes, proportions, angles, numbers, etc. disclosed in the drawings to illustrate embodiments are examples and are not intended to be limiting to those shown herein.

Although first, second, and the like are used to describe various components, the components are not limited by these terms. Thus, a first component referred to herein may also be a second component within the technical idea of the present invention.

Each of the features of the various embodiments disclosed herein may be combined or combinable with each other, in part or in whole, and may be technically interlocked and operated in a variety of ways, and each embodiment may be practiced independently of or in conjunction with one another.

Aspects of some embodiments will be described in more detail below with reference to the accompanying drawings. Configurations that function substantially the same between embodiments are given the same drawing designation and some repeated description may be omitted.

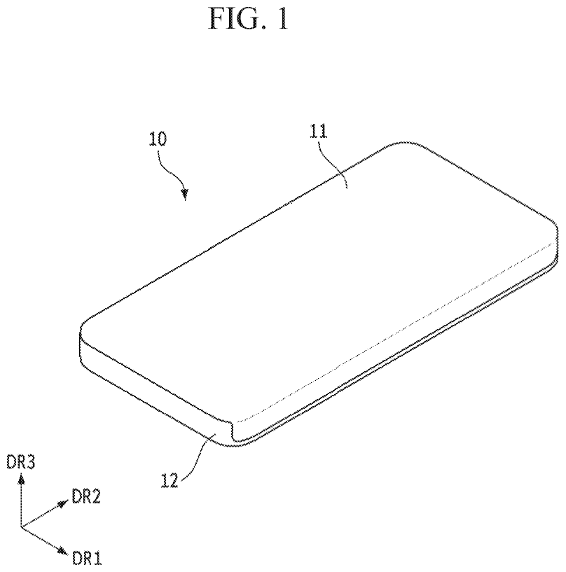

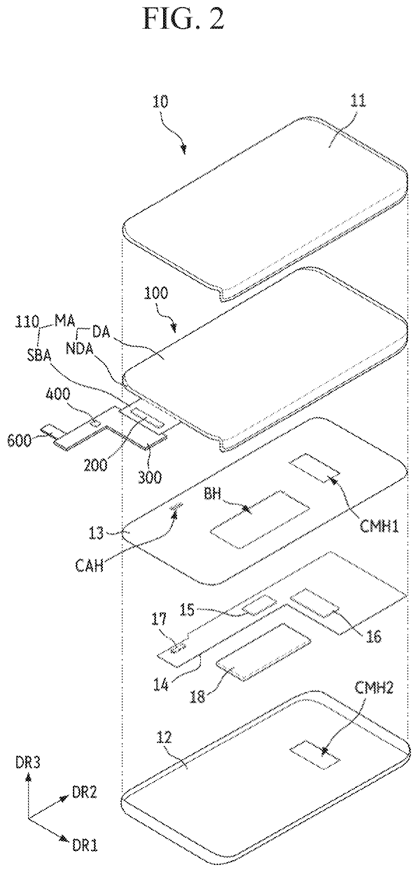

FIG. 1 is a perspective view illustrating an electronic device according to some embodiments of the present disclosure. FIG. 2 is an exploded perspective view of the electronic device according to some embodiments of the present disclosure.

Referring to FIG. 1, an electronic device 10 according to some embodiments is a device having a function of displaying an image on a display area. The electronic device 10 may provide portability. As an example, the electronic device 10 may be a portable electronic device such as a mobile phone, a smartphone, a tablet personal computer (PC), a smart watch, a watch phone, a mobile communication terminal, an electronic notebook, an electronic book, a portable multimedia player (PMP), a navigation device, or an ultra mobile personal computer (UMPC).

However, the electronic device 10 according to some embodiments is not limited to the portable electronic device, and may also be a large device such as a television, a laptop computer, a monitor, a billboard, or the Internet of Thing (IOT).

The electronic device 10 according to some embodiments may include a cover window 11 and a lower cover 12 that are provided as a housing protecting a display device.

Referring to FIG. 2, the electronic device 10 may further include a display device 100, a bracket 13, and a main circuit board 14 that are housed between the cover window 11 and the lower cover 12.

The display device 100 may include a main area MA including a display area DA in which an image display is implemented and a non-display area NDA, which is a peripheral area (e.g., surrounding, in a periphery, or outside a footprint) of the display area DA, and a sub-area SBA protruding from one side of the main area MA.

The display device 100 may further include a display driving circuit 200 located in the sub-area SBA, a display circuit board 300 bonded to one side of the sub-area SBA, a touch driving circuit 400 mounted on the display circuit board 300, and a cable 600 extending from one side of the display circuit board 300.

A first direction DR1 as used herein may be a direction parallel to a short side of the electronic device 10, that is, a transverse direction of the electronic device 10, in a plan view. A second direction DR2 as used herein may be a direction parallel to a long side of the electronic device 10, that is, a longitudinal direction of the electronic device 10, in a plan view. A third direction DR3 as used herein may be a thickness direction of the electronic device 10.

The electronic device 10 may have a shape similar to a rectangular shape in a plan view. For example, the electronic device 10 may have a rectangular shape, in a plan view, having short sides in the first direction DR1 and long sides in the second direction DR2. A corner where the short side in the first direction DR1 and the long side in the second direction DR2 meet may be rounded with a selected curvature or right-angled. The shape of the electronic device 10 in a plan view is not limited to the rectangular shape, and may be other polygonal shapes, a circular shape, an elliptical shape, or an irregular shape.

The cover window 11 may be located above the display device 100 so as to cover an upper surface of the display device 100. The cover window 11 may serve to protect the upper surface of the display device 100. The cover window 11 may include a light transmitting portion that is transparent and a light blocking portion that is opaque. The light transmitting portion may overlap the display area DA of the display device 100 in the third direction DR3, and the light blocking portion may overlap the non-display area NDA of the display device 100 in the third direction DR3.

The cover window 11 may include an upper surface portion forming an upper surface of the electronic device 10, a left surface portion forming a left surface of the electronic device 10, and a right surface portion forming a right surface of the electronic device 10. The left surface portion of the cover window 11 may extend from the left side of the upper surface portion, and the right surface portion of the cover window 11 may extend from the right side of the upper surface portion.

Each of the upper surface portion, the left surface portion, and the right surface portion of the cover window 11 may include a light transmitting portion and a light blocking portion.

The light transmitting portion of the cover window 11 may be located in most of each of the upper surface portion, the left surface portion, and the right surface portion of the cover window 11.

The light blocking portion of the cover window 11 may be located at an upper edge and a lower edge of the upper surface portion of the cover window 11, an upper edge, a left edge, and a lower edge of the left surface portion of the cover window 11, and an upper edge, a right edge, and a lower edge of the right surface portion of the cover window 11.

The display device 100 may be located below the cover window 11.

That is, the cover window 11 may be located on the display device 100.

The display device 100 may include an upper surface portion facing the upper surface portion of the cover window 11, a left surface portion facing the left surface portion of the cover window 11, and a right surface portion facing the right surface portion of the cover window 11. The left surface portion of the display device 100 may extend from the left side of the upper surface portion, and the right surface portion of the display device 100 may extend from the right side of the upper surface portion.

The display device 100 may include a main area MA, which is a display surface, and a sub-area SBA protruding from at least a portion of one side of the main area MA.

The main area MA may include a display area DA displaying images and a non-display area NDA, which is a peripheral area (e.g., surrounding, in a periphery, or outside a footprint) of the display area DA, and may not display images.

The display area DA may be located in most of the main area MA. The display area DA may be located at the center of the main area MA.

In other words, each of the upper surface portion, the left surface portion, and the right surface portion of the display device 100 may include a display area DA and a non-display area NDA.

The display area DA may be located in most of each of the upper surface portion, the left surface portion, and the right surface portion of the display device 100.

The non-display area NDA may be located outside the display area DA. The non-display area NA may be an edge area of the main area MA.

The non-display area NDA may be located at an upper edge and a lower edge of the upper surface portion of the display device 100, an upper edge, a left edge, and a lower edge of the left surface portion of the display device 100, and an upper edge, a right edge, and a lower edge of the right surface portion of the display device 100.

The sub-area SBA may protrude from one side of the main area MA in the second direction DR2.

A length of the sub-area SBA in the first direction DR1 may be smaller than or equal to a length of the main area MA in the first direction DR1. A length of the sub-area SBA in the second direction DR2 may be smaller than a length of the main area MA in the second direction DR2, but is not limited thereto.

A portion of the sub-area SBA is transformed into a bent shape, such that another portion of the sub-area SBA may overlap the main area MA in the third direction DR3.

The display driving circuit 200 may be mounted in the sub-area SBA, and the display circuit board 300 may be attached to the sub-area SBA.

One end of the display circuit board 300 may be attached onto pads located at a lower edge of the sub-area SBA of the display device 100 using an anisotropic conductive film.

The display circuit board 300 may be a flexible printed circuit board (FPCB) that may be bent, a rigid printed circuit board (PCB) that maintains a flat shape, or a composite printed circuit board that includes both a rigid printed circuit board and a flexible printed circuit board.

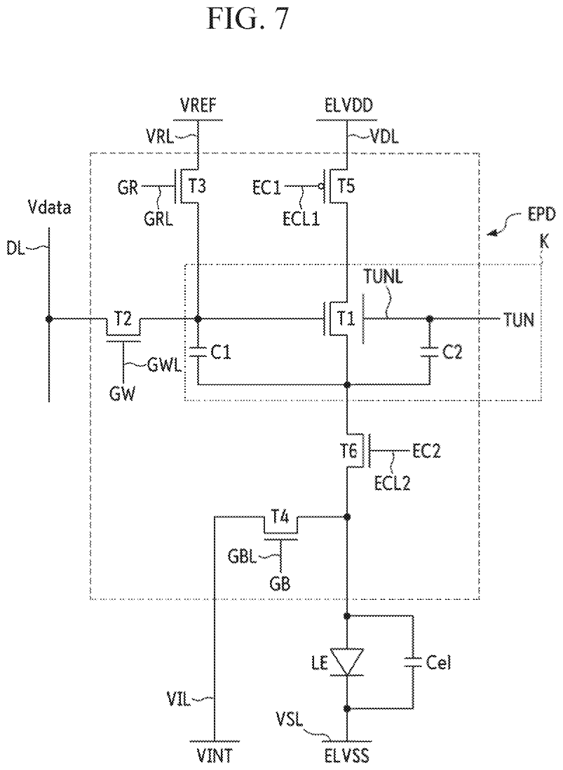

The display driving circuit 200 may transmit data signals Vdata (see FIG. 7) of each of pixel circuits EPD (see FIG. 7) of the display area DA to data lines DL (see FIG. 7) based on control signals, power, and voltages supplied through the display circuit board 300.

The display driving circuit 200 may be provided as an integrated circuit (IC) and mounted on the sub-area SBA of the display device 100 in a chip on glass (COG) manner, a chip on plastic (COP) manner, or an ultrasonic manner. However, this is only an example, and embodiments according to the present disclosure are not limited thereto. For example, the display driving circuit 200 may also be mounted on the display circuit board 300.

According to some embodiments, the touch driving circuit 400 may be further mounted in the sub-area SBA of the display device 100. Alternatively, the touch driving circuit 400 may be mounted on the display circuit board 300.

The touch driving circuit 400 may be electrically connected to a touch sensor layer of the display device 100.

The bracket 13 may be located below the display device 100. The bracket 13 may include plastic or metal. The bracket 13 may include a first camera hole CMH1 into which a camera device 16 is inserted, a battery hole BH in which a battery 18 is located, and a cable hole CAH through which the cable 600 connected to the display circuit board 300 passes.

The main circuit board 14 and the battery 18 may be located below the bracket 13.

The main circuit board 14 may be a printed circuit board or a flexible printed circuit board.

The main circuit board 14 may include a main processor 15, the camera device 16, and a main connector 17. The main processor 15 may be formed as an integrated circuit.

The camera device 16 may be located on both upper and lower surfaces of the main circuit board 14, the main processor 15 may be located on the upper surface of the main circuit board 14, and the main connector 17 may be located on the upper surface of the main circuit board 14.

The main processor 15 may control all functions of the electronic device 10.

For example, the main processor 15 may output digital video data to the display driving circuit 200 through the display circuit board 300 so that the display device 100 displays an image. In addition, the main processor 15 may receive touch data including a touch coordinates of a user from the touch driving circuit 400, decide whether or not the user has performed a touch or whether or not the user has performed approach, and then execute an operation corresponding to a touch input or an approach input of the user. For example, the main processor 15 may execute an application or perform an operation indicated by an icon touched by the user.

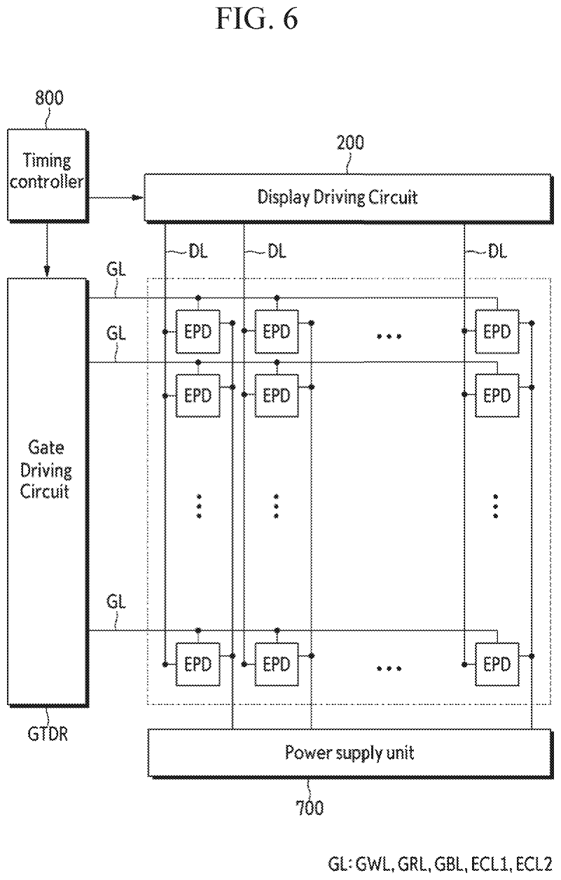

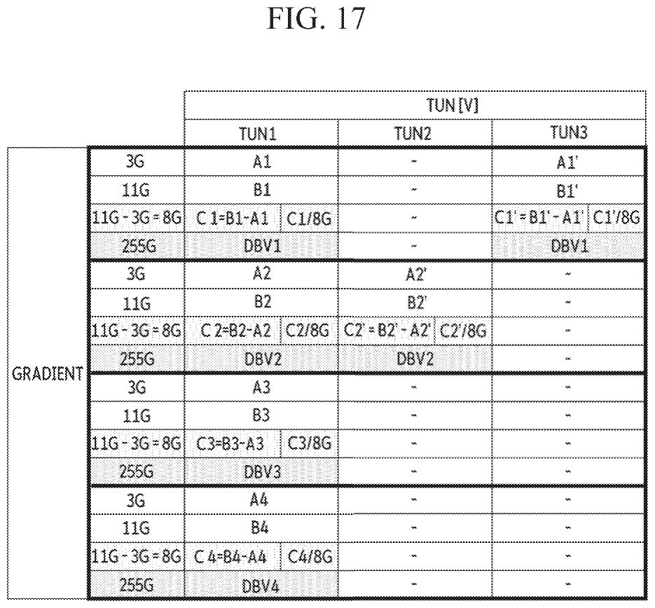

In addition, the main processor 15 may include a graphic processing unit (GPU). The main processor 15 or the GPU may provide a control signal to a controller 800 (see FIG. 6) (e.g., a timing controller (T-CON)). The control signal may include a brightness value (see FIG. 17) (or a display brightness value (DBV). For example, the brightness value may represent a display panel luminance at the highest grayscale (e.g., a 255-th grayscale (255G)), but embodiments according to the present disclosure are not limited thereto.

The main processor 15 may be an application processor, a central processing unit, or a system chip formed as an integrated circuit.

The camera device 16 processes an image frame such as a still image or a moving image obtained by an image sensor in a camera mode and outputs the processed image frame to the main processor 15.

The cable 600 passing through the cable hole CAH of the bracket 13 may be connected to the main connector 17. For this reason, the main circuit board 14 may be electrically connected to the display circuit board 300.

The battery 18 may not overlap the main circuit board 14 in the third direction DR3. The battery 18 may overlap the battery hole BH of the bracket 13 in the third direction DR3.

In addition, a mobile communication module capable of transmitting and receiving wireless signals to and from at least one of a base station, an external terminal, or a server over a mobile communication network may be further mounted on the main circuit board 14. The wireless signal may include various types of data according to transmission/reception of a voice signal, a video call signal, or a text/multimedia message.

The lower cover 12 may be located below the main circuit board 14 and the battery 18. The lower cover 12 may be fastened and fixed to the bracket 13. The lower cover 12 may form an upper side surface, a lower side surface, and a lower surface of the electronic device 10. The lower cover 12 may include plastic, metal, or both plastic and metal.

The lower cover 12 may include a second camera hole CMH2 through which a lower surface of the camera device 16 is exposed. A location of the camera device 16 and locations of the first camera hole CMH1 and the second camera hole CMH2 that correspond to the camera device 16 are not limited to those illustrated in FIG. 2.

Next, a display device 100 according to some embodiments will be described in more detail.

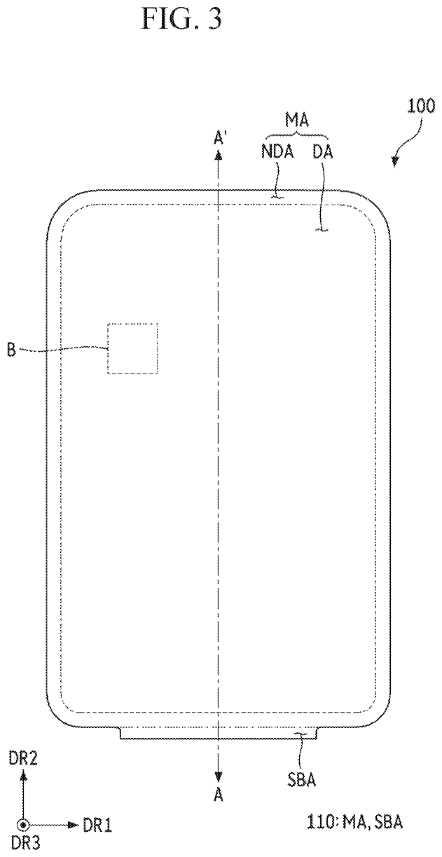

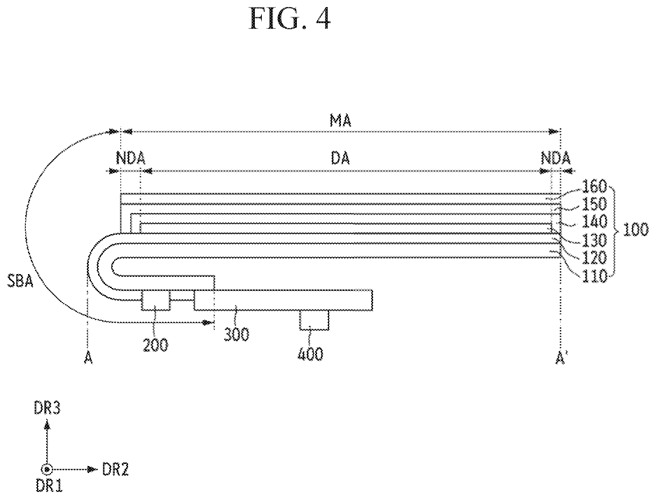

FIG. 3 is a plan view illustrating a display device of FIG. 2. FIG. 4 is a cross-sectional view taken along the line A-A′ of FIG. 3.

Referring to FIGS. 3 and 4, a display device 100 according to embodiments is a device that displays a moving image (e.g., video images) or a still image (e.g., static images), and may be used as a display screen of various products such as televisions, laptop computers, monitors, billboards, and the Internet of Things (IOT) as well as portable electronic devices such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs).

The display device 100 may be a light emitting display device such as an organic light emitting display device using organic light emitting diodes, a quantum dot light emitting display device including quantum dot light emitting layers, an inorganic light emitting display device including inorganic semiconductors, and a micro light emitting display device using micro or nano light emitting diodes (micro LEDs or nano LEDs). Hereinafter, it will be mainly described that the display device 100 is an organic light emitting display device. However, embodiments according to the present disclosure are not limited thereto, and may be applied to a display device including an organic insulating material, an organic light emitting material, and a metal material.

The display device 100 may be formed to be flat, but is not limited thereto. For example, the display device 100 may include curved surface portions formed at left and right ends thereof and having a constant curvature or a variable curvature. In addition, the display device 100 may be flexibly formed to be curved, bent, folded, or rolled.

Referring to FIG. 3, at least one surface of the display device 100 includes a main area MA from which light for displaying images is emitted.

The display area DA may be formed in a rectangular shape, in a plan view, having short sides in the first direction DR1 and long sides in the second direction DR2 crossing the first direction DR1. A corner where the short side in the first direction DR1 and the long side in the second direction DR2 meet may be rounded with a selected curvature or right-angled. A shape of the display area DA in a plan view is not limited to the rectangular shape, and may be other polygonal shapes, a circular shape, or an elliptical shape.

The display area DA may be located in most of the main area MA. The display area DA may be located at the center of the main area MA.

Referring to FIG. 4, the display device 100 may further include a sub-area SBA may protrude from at least a portion of one side of the main area MA in the second direction DR2.

A portion of the sub-area SBA is transformed into a bent shape, such that another portion of the sub-area SBA may be located on a rear surface of the display device 100.

According to some embodiments, the display device 100 includes a substrate 110, a circuit layer 120 located on the substrate 110, and an element layer 130 located on the circuit layer 120.

The display device 100 may further include a sealing layer 140 located on the element layer 130 and a touch sensor layer 150 located on the sealing layer 140.

The display device 100 may further include a polarizing layer 160 located on the touch sensor layer 150 in order to relatively reduce external light reflection.

The substrate 110 may include a main area MA corresponding to a display surface and a sub-area SBA protruding from at least a portion of one side of the main area MA.

The main area MA of the substrate 110 may include a display area DA from which light is emitted and a non-display area NA arranged around (e.g., in a periphery or outside a footprint of) the display area DA.

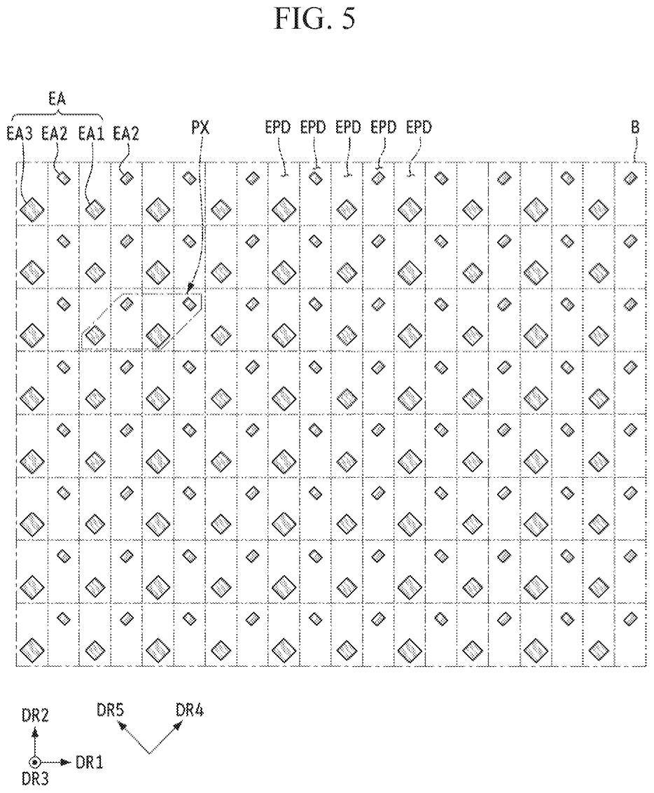

According to some embodiments, the element layer 130 may include light emitting elements LE (see FIG. 7) respectively located in emission areas EA (see FIG. 5).

The circuit layer 120 may include pixel circuits EPD (see FIG. 5) electrically connected to the light emitting elements LE and at least one constant voltage line transmitting at least one constant voltage to the pixel circuits EPD.

At least one constant voltage line may include a first driving voltage line VDL (see FIG. 7) transmitting a first driving voltage ELVDD (see FIG. 7), an initialization voltage line VIL (see FIG. 7) transmitting an initialization voltage VINT (see FIG. 7), and a reference voltage line VRL (see FIG. 7) transmitting a reference voltage VREF (see FIG. 7).

The circuit layer 120 may further include data lines DL (see FIGS. 6 and 7) transmitting the data signals Vdata (see FIG. 7) of the pixel circuits EPD (see FIG. 5).

The sealing layer 140 may cover the element layer 130. The sealing layer 140 may include a structure in which two or more inorganic films and at least one organic film are alternately stacked.

The touch sensor layer 150 may be located on the sealing layer 140, and may correspond to the main area MA. The touch sensor layer 150 may include touch electrodes for sensing a touch of a person or an object.

The polarizing layer 160 is used to prevent or reduce deterioration of visibility of an image due to external light reflection by blocking external light reflected from the touch sensor layer 150, the sealing layer 140, the element layer 130, and the circuit layer 120 and interfaces between these layers.

As a portion of the sub-area SBA is transformed into the bent shape, the display driving circuit 200 mounted on the sub-area SBA and the display circuit board 300 connected to one side of the sub-area SBA may be located under the substrate 110.

The display driving circuit 200 may be electrically connected to the data lines DL (see FIGS. 6 and 7) of the circuit layer 120. The display driving circuit 200 may transmit the data signals Vdata (see FIG. 7) of the pixel circuits EPD (see FIG. 5) through the data lines DL based on control signals and source voltages supplied from the display circuit board 300.

The display driving circuit 200 may be provided as an integrated circuit (IC) and mounted on the sub-area SBA of the display device 100 in a chip on glass (COG) manner, a chip on plastic (COP) manner, or an ultrasonic manner. However, this is only an example, and embodiments according to the present disclosure are not limited thereto. For example, the display driving circuit 200 may also be mounted on the display circuit board 300.

One end of the display circuit board 300 may be attached onto pads located at an edge of one side of the sub-area SBA of the display device 100 using an anisotropic conductive film.

The display circuit board 300 may be a flexible printed circuit board (FPCB) that may be bent, a rigid printed circuit board (PCB) that maintains a flat shape, or a composite printed circuit board that includes both a rigid printed circuit board and a flexible printed circuit board.

The display circuit board 300 may be connected to signal pads located on one side of the sub-area SBA.

The touch driving circuit 400 may be mounted on the display circuit board 300.

The touch driving circuit 400 may be electrically connected to the touch sensor layer 150 of the display device 100.

The touch driving circuit 400 may apply touch driving signals to driving lines of the touch sensor layer 150 and receive touch sensing signals from sensing lines. In addition, the touch driving circuit 400 may decide whether or not the user has performed a touch, whether or not the user has performed approach, or the like, by sensing charge change amounts of capacitance based on the touch sensing signals.

The touch of the user indicates that a user's finger or an object such as a pen comes into direct contact with an upper surface of the cover window located on the touch sensor layer The approach of the user indicates that the user's finger or the object such as the pen hovers above the upper surface of the cover window.

The touch driving circuit 400 may output touch data including a touch coordinates of the user to the main processor 15 (see FIG. 2).

FIG. 5 is a plan view illustrating portion B of FIG. 3.

As illustrated in FIG. 5, the display area DA may include emission areas EA where light is emitted and a non-emission area which is an area between the emission areas EA spaced apart from each other and where light is not emitted.

Each of the emission areas EA may be a unit area emitting light of a wavelength band corresponding to one of two or more different colors with a luminance corresponding to an image signal.

Each of the emission areas EA may be arranged in a quadrangular shape.

However, this is only an example, and a shape of each of the emission areas EA according to some embodiments in a plan view is not limited to that illustrated in FIG. 5. That is, each of the emission areas EA may have a polygonal shape such as a rectangular shape, a square shape, a hexagonal shape, or an octagonal shape other than a rhombic shape, a circular shape, or an elliptical shape, in a plan view.

The emission areas EA may include first emission areas EA1 emitting light of a first wavelength band, second emission areas EA2 emitting light of a second wavelength band lower than the first wavelength band, and third emission areas EA3 emitting light of a third a wavelength band lower than the second wavelength band.

As an example, the first wavelength band may be 600 nanometers (nm) to 750 nm (or about 600 nm to about 750 nm), and may correspond to red. The second wavelength band may be 480 nm to 560 nm (or about 480 nm to about 560 nm), and may correspond to green. The third wavelength band may be 370 nm to 460 nm (or about 370 nm to about 460 nm), and may correspond to blue.

However, this is only an example, and the first wavelength band, the second wavelength band, and the third wavelength band according to some embodiments are not limited thereto.

As the emission areas EA include the first emission areas EA1, the second emission areas EA2, and the third emission areas EA3, unit pixels PX may be respectively provided by combinations of one or more first emission areas EA1, one or more second emission areas EA2, and one or more third emission areas EA3 adjacent to each other among the emission areas EA.

Each of the unit pixels PX may be a unit displaying various colors including white. That is, light of various colors displayed by each unit pixel PX may be implemented by color mixing of light emitted from two or more emission areas EA included in each unit pixel PX.

The third emission area EA3 may have a greater width than the first emission area EA1, and the first emission area EA1 may have a greater width than the second emission area EA2. However, this is only an example, and a width of each of the emission areas EA is not limited to that illustrated in FIG. 5.

The first emission areas EA1 and the third emission areas EA3 may be alternately arranged in the first direction DR1.

The second emission areas EA2 may be arranged side by side in the second direction DR2.

Each of the second emission areas EA2 may neighbor to the first emission area EA1 or the third emission area EA3 in diagonal directions DR4 and DR5 crossing the first direction DR1 and the second direction DR2.

In this case, each of the unit pixels PX may include one first emission area EA1 and one third emission area EA3 neighboring to each other in the first direction DR1 and two second emission areas EA2 neighboring to one first emission area EA1 and one third emission area EA3 in the diagonal directions DR4 and DR5. However, this is only an example, and an arrangement form of the emission areas EA according to some embodiments and components of the unit pixel PX are not limited to those described above.

According to some embodiments, the circuit layer 120 (see FIG. 4) may include pixel circuits EPD arranged in the first direction DR1 and the second direction DR2 in the display area DA.

The pixel circuits EPD may be electrically connected to the light emitting elements LE (see FIG. 7) of the element layer 130 (see FIG. 4), respectively. The light emitting elements LE may be located in the emission areas EA, respectively.

FIG. 6 is a block diagram illustrating the display device of FIG. 2.

Referring to FIG. 6, the circuit layer 120 of the display device 100 according to some embodiments may include pixel circuits EPD electrically connected to the light emitting elements LE (see FIG. 7) located in the emission areas EA of the display area DA and one or more gate lines GL transmitting one or more gate signals to the pixel circuits EPD.

The circuit layer 120 may further include data lines DL transmitting data signals Vdata (see FIG. 7) of the pixel circuits EPD.

According to some embodiments, the display device 100 may further include a display driving circuit 200 outputting the data signals Vdata (see FIG. 7) of the pixel circuits EPD to the data lines DL in order to control a luminance of each of the light emitting elements LE (see FIG. 7).

According to some embodiments, the display device 100 may further include a gate driving circuit GTDR outputting gate signals to the gate lines GL, a power supply unit 700 supplying power and voltages to the pixel circuits EPD, and a timing controller 800 controlling a driving timing of each of the display driving circuit 200 and the gate driving circuit GTDR.

The timing controller 800 receives an image signal supplied from the outside of the display device 100.

The timing controller 800 may output image data DATA and a data control signal DCS to the display driving circuit 200.

The timing controller 800 may generate a scan control signal SCS for controlling an operation timing of the gate driving circuit GTDR.

The display driving circuit 200 may convert the image data DATA into analog data voltages and output the analog data voltages to the data lines DL.

The gate driving circuit GTDR may generate gate signals according to the scan control signal SCS and sequentially output the gate signals to the gate lines GL.

The gate lines GL may include a write scan line GWL transmitting a write scan signal GW (see FIG. 7), a reset control line GRL transmitting a reset control signal GR (see FIG. 7), a bias control line GBL transmitting a bias scan signal GB (see FIG. 7), a first emission control line ECL1 transmitting a first emission control signal EC1 (see FIG. 7), and a second emission control line ECL2 transmitting a second emission control signal EC2 (see FIG. 7).

The gate signals may have pulses changed into a first gate level voltage or a second gate level voltage.

The power supply unit 700 may supply various power and voltages required for driving the pixel circuits EPD.

As an example, the power supply unit 700 may supply a first driving voltage ELVDD (see FIG. 7) and a second driving voltage ELVSS (see FIG. 7) for generating driving signals transmitted to the light emitting elements LE, a reference voltage VREF (see FIG. 7) for initializing the pixel circuits EPD, and an initialization voltage VAINT (see FIG. 7) for initializing the light emitting elements LE (see FIG. 7).

FIG. 7 is an equivalent circuit diagram illustrating a pixel circuit according to some embodiments of the present disclosure. Although FIG. 7 illustrates various components in a pixel circuit according to some embodiments, embodiments according to the present disclosure are not limited thereto, and according to various embodiments the pixel circuit may include additional components, or fewer components, without departing from the spirit and scope of embodiments according to the present disclosure.

A circuit located in the present disclosure may include a plurality of transistors. The transistors may be an oxide thin film transistor (TFT) including an oxide semiconductor or an LTPS TFT including low temperature poly silicon (LTPS).

A transistor is a three-electrode switching element including a gate, a source, and a drain. The source is an electrode supplying carriers to the transistor In the transistor, the carriers start to flow from the source. The drain is an electrode through which carriers exit the transistor. In the transistor, the carriers flow from the source to the drain.

In a case of an n-channel transistor, the carriers are electrons, and thus, a source voltage is lower than a drain voltage so that the electrons may flow from the source to the drain. In the n-channel transistor, a current flows from the drain toward the source. In a case of a p-channel transistor, the carriers are holes, and thus, a source voltage is higher than a drain voltage so that the holes may flow from the source to the drain. In the p-channel transistor, the holes flow from the source toward the drain, and thus, a current flows from the source toward the drain. It is to be noted that the source and the drain of the transistor are not fixed. For example, the source and the drain may be changed depending on an applied voltage. Accordingly, the present disclosure is not limited by the source and the drain of the transistor.

In the following description, a first electrode, a second electrode, and a gate electrode of the transistor may all be referred to as electrodes of the transistor. In addition, a source electrode and a drain electrode of the transistor may be referred to as a first electrode and a second electrode, respectively. For example, any transistor may include a first electrode and a second electrode. When the first electrode of any transistor is a source electrode, the second electrode of any transistor may be a drain electrode. When the second electrode of any transistor is a source electrode, the first electrode of any transistor may be a drain electrode. The distinguishment between the source and the drain is changed depending on whether the transistor is implemented as an n-channel transistor or a p-channel transistor, and in the present disclosure, the terms “first electrode” and “second electrode” will be used regardless of whether the transistor is an n-channel transistor or a p-channel transistor.

Referring to FIG. 7, a pixel circuit EPD may be electrically connected to a light emitting element LE. The pixel circuit EPD may be electrically connected to a first driving voltage line VDL transmitting a first driving voltage ELVDD, which is a constant voltage, and the light emitting element LE may be electrically connected to a second driving voltage line VSL transmitting a second driving voltage ELVSS different from the first driving voltage ELVDD. The second driving voltage ELVSS, which is a constant voltage, may have a voltage level lower than that of the first driving voltage ELVDD.

In addition, a third driving voltage TUN, which is a constant voltage, may be applied as a back gate voltage to a first transistor T1. The third driving voltage TUN may be the same as or different from the first driving voltage ELVDD. A back gate electrode of the first transistor T1 may be electrically connected to a third driving voltage line TUNL transmitting the third driving voltage TUN.

An anode electrode of the light emitting element LE may be electrically connected to the pixel circuit EPD, and a cathode electrode of the light emitting element LE may be electrically connected to the second driving voltage line VSL. The pixel circuit EPD may be electrically connected to a data line DL transmitting a data signal Vdata, a reference voltage line VRL transmitting a reference voltage VREF, and an initialization voltage line VIL transmitting an initialization voltage VINT.

The pixel circuit EPD may be electrically connected to a write scan line GWL transmitting a write scan signal GW, a reset control line GRL transmitting a reset control signal GR, a bias scan line GBL transmitting a bias scan signal GB, a first emission control line ECL1 transmitting a first emission control signal EC1, and a second emission control line ECL2 transmitting a second emission control signal EC2.

The pixel circuit EPD may include the first transistor T1 (or a driving transistor) generating a driving current of the light emitting element LE, two or more transistors T2 to T6 electrically connected to the first transistor T1, and one or more capacitors C1 and C2.

A second transistor T2 may be electrically connected between a gate electrode of the first transistor T1 and the data line DL. The second transistor T2 may be turned on by the write scan signal GW of the write scan line GWL. When the second transistor T2 is turned on, the data signal Vdata of the data line DL may be transmitted to the gate electrode of the first transistor T1.

When a voltage difference between the gate electrode of the first transistor T1 and a first electrode (e.g., a source electrode) of the first transistor T1 becomes greater than or equal to a threshold voltage of the first transistor T1 by the data signal Vdata applied to the gate electrode of the first transistor T1, the first transistor T1 may be turned on. Accordingly, a drain-source current of the first transistor T1 may be generated in a magnitude corresponding to the data signal Vdata.

A third transistor T3 may be electrically connected between the gate electrode of the first transistor T1 and the reference voltage line VRL. The third transistor T3 may be turned on by the reset control signal GR of the reset control line GRL. When the third transistor T3 is turned on, a potential of the gate electrode of the first transistor T1 may be initialized to the reference voltage VREF of the reference voltage line VRL.

A fourth transistor T4 may be electrically connected between the light emitting element LE and the initialization voltage line VIL. The fourth transistor T4 may be turned on by the bias scan signal GB of the bias scan line GBL. When the fourth transistor T4 is turned on, a potential of the anode electrode of the light emitting element LE may be initialized to the initialization voltage VINT of the initialization voltage line VIL.

A fifth transistor T5 may be electrically connected between a second electrode of the first transistor T1 and the first driving voltage line VDL. The fifth transistor T5 may be turned on by the first emission control signal EC1 of the first emission control line ECL1.

A sixth transistor T6 may be electrically connected between the first electrode of the first transistor T1 and the light emitting element LE. The sixth transistor T6 may be turned on by the second emission control signal EC2 of the second emission control line ECL2.

When the fifth transistor T5 and the sixth transistor T6 are turned on, the first transistor T1 and the light emitting element LE may be connected to each other in series between the first driving voltage ELVDD and the second driving voltage ELVSS, and thus, the drain-source current of the first transistor T1 generated in the magnitude corresponding to the data signal Vdata may be transmitted to the light emitting element LE. Consequently, the light emitting element LE may emit light of a luminance corresponding to the data signal Vdata.

A first group capacitor C1 may be electrically connected between the gate electrode of the first transistor T1 and the first electrode of the first transistor T1. Accordingly, the first group capacitor C1 may be charged with the data signal Vdata applied to the gate electrode of the first transistor T1, and a turn-on state of the first transistor T1 may be maintained for a selected period due to a voltage charged in the first group capacitor C1.

A second group capacitor C2 may be electrically connected between the first electrode of the first transistor T1 and the third driving voltage line TUNL. The voltage of the first group capacitor C1 may correspond to a potential difference between the gate electrode of the first transistor T1 and the first electrode of the first transistor T1, may be changed by the data signal Vdata, and may be divided by the second group capacitor C2. Accordingly, the threshold voltage of the first transistor T1 may be compensated for.

According to some embodiments, the first transistor T1 may include the gate electrode facing one surface of a channel portion and the back gate electrode facing the other surface of the channel portion. The channel portion (or a first channel portion) of the first transistor T1 may be located between the gate electrode and the back gate electrode.

The gate electrode of the first transistor T1 may be electrically connected to the second transistor T2. The back gate electrode of the first transistor T1 may be electrically connected to the third driving voltage line TUNL.

Accordingly, when the data signal Vdata is applied to the gate electrode of the first transistor T1 and the first transistor T1 is in a turn-on state, a portion of the channel portion of the first transistor T1 adjacent to the gate electrode may be activated, while the remaining portion of the channel portion of the first transistor T1 adjacent to the back gate electrode may not be activated.

Therefore, electron mobility of the channel portion of the first transistor T1 may be reduced, and a gradient of a driving current curve indicating a relationship between a voltage of the gate electrode and a source-drain current of the first transistor T1 may become gradual. Accordingly, a driving voltage range of the first transistor T1 may be increased, and thus, easiness in controlling a luminance may be relatively improved.

According to some embodiments, the first transistor T1 may be an n-channel transistor, and at least some of the second to sixth transistors T2 to T6 may be p-channel transistors. As an example, the fifth transistor T5 may be a p-channel transistor, and the second transistor T2, the third transistor T3, the fourth transistor T4, and the sixth transistor T6 may be n-channel transistors.

According to some embodiments, the first transistor T1 may be an oxide TFT including an oxide semiconductor. The oxide TFTs have a similar threshold voltage between pixels compared to LTPS TFTs. Accordingly, when the oxide TFTs are used as driving transistors, uniformity related to threshold voltage characteristics of the driving transistors across the entire screen may be relatively improved.

Because a channel layer of the oxide TFT is manufactured based on an amorphous semiconductor, there may be a difference in threshold voltage between the driving transistors across the entire display panel. However, because there is hardly a difference in threshold voltage between pixels within a local area, the uniformity described above may be relatively improved. In the LTPS TFT, due to characteristics of polycrystalline silicon, a difference in threshold voltage between adjacent driving transistors may become great depending on a location of a grain boundary.

In the pixel circuit EPD, when the first transistor T1 includes the oxide semiconductor, display quality may be relatively improved due to the improvement of the uniformity, but a gradient of the driving current curve may become gradual at a low luminance and/or a low grayscale as described later (see FIG. 17).

The present disclosure proposes a system and method for preventing or reducing a problem that a gradient of a driving current curve becomes excessively gradual at a low luminance and/or a low grayscale to deteriorate low grayscale expressiveness of a display device. As an example, in order to prevent or reduce the gradient of the driving current curve from becoming gradual at the low luminance/low grayscale, a different voltage may be applied to the back gate electrode of the first transistor T1 according to a luminance/grayscale. Such a voltage may be the third driving voltage TUN.

Unlike applying the first driving voltage ELVDD as the back gate voltage of the first transistor T1 at all luminances/grayscales, the third driving voltage TUN is applied as the back gate voltage of the first transistor T1 in the pixel circuit EPD according to some embodiments of the present disclosure. The third driving voltage TUN may be the same as the first driving voltage ELVDD at some luminances/grayscales and different from the first driving voltage ELVDD at the other luminances/grayscales.

A control signal input to the display device may include a brightness value (display brightness value (DBV)), and the brightness value may correspond to a maximum brightness value (255-th grayscale (255G)). A plurality of pixel circuits located in the display device so as to correspond to an arbitrary brightness value receive data voltages divided into 256 grayscale values. 256 grayscales may be divided into low grayscales with relatively low values and high grayscales with relatively high values. The driving current curve may have a positive gradient in a range where the first transistor T1 is turned on, and the gradient of the driving current curve is defined as a ratio of a change amount in driving current (corresponding to a luminance) to a change amount in input data voltage value (corresponding to a grayscale value).

As the corresponding brightness value decreases, the gradient of the driving current curve corresponding to the low grayscale may become gradual. Because the gradient of the driving current curve becomes gradual, a change amount in luminance corresponding to an input data voltage decreases as the brightness value decreases. In other words, as the brightness value decreases, luminance sensitivity to a change amount in data voltage decreases.

The present disclosure provides a means for preventing or reducing a decrease in expressiveness at the low luminance/low grayscale as described above. In other words, the present disclosure provides a means capable of changing the gradient of the driving current curve according to a brightness value. The third driving voltage TUN input when the brightness value is relatively low may be different from the third driving voltage TUN input when the brightness value is relatively high. The gradient of the driving current curve corresponding to a low-grayscale region at a relatively low brightness value changes as the third driving voltage TUN is differently input.

When values input as the third driving voltages TUN at both a relatively low brightness value and a relatively high brightness value are the same as each other, the gradient of the driving current curve corresponding to the low-grayscale region decreases as the brightness value decreases. However, when values input as the third driving voltages TUN at both the relatively low brightness value and the relatively high brightness value are different from each other, the gradient of the driving current curve corresponding to the low-grayscale region decreases may remain the same even though the brightness value decreases or may increase as the brightness value decreases.

Accordingly, the display device according to some embodiments of the present disclosure may relatively improve/enhance luminance sensitivity to a change amount in data voltage in a low-luminance/low-grayscale region, and display quality of the display device may be relatively improved.

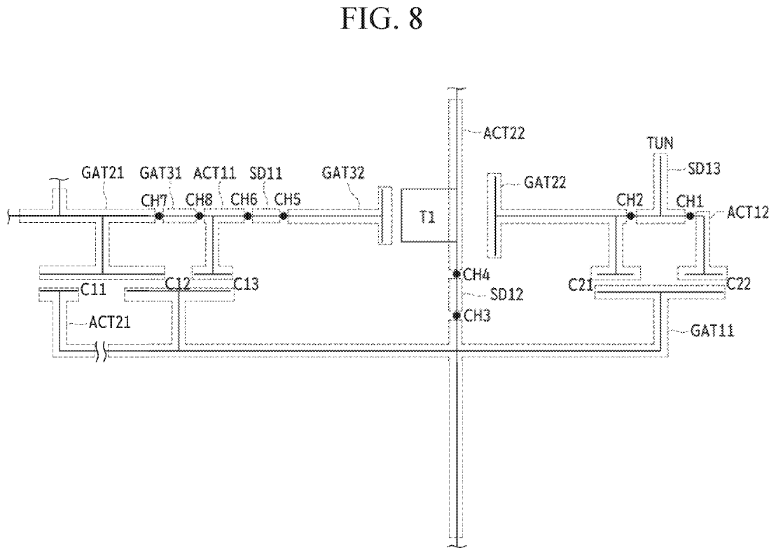

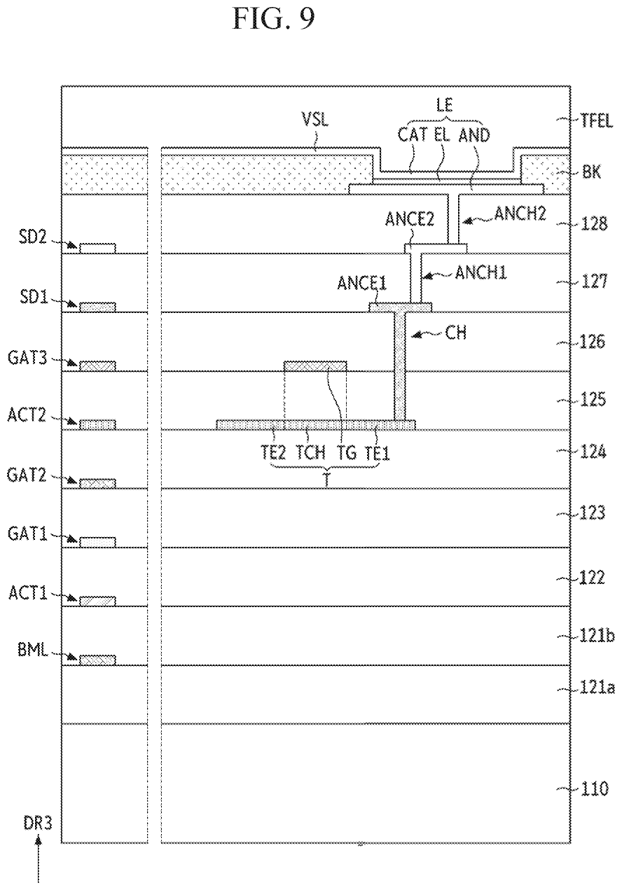

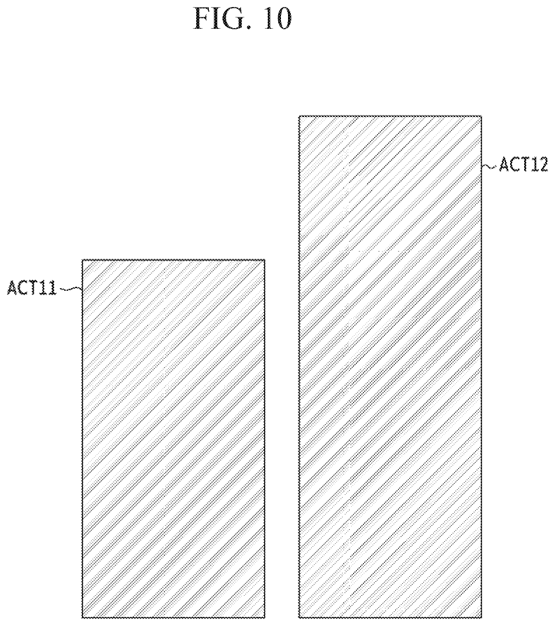

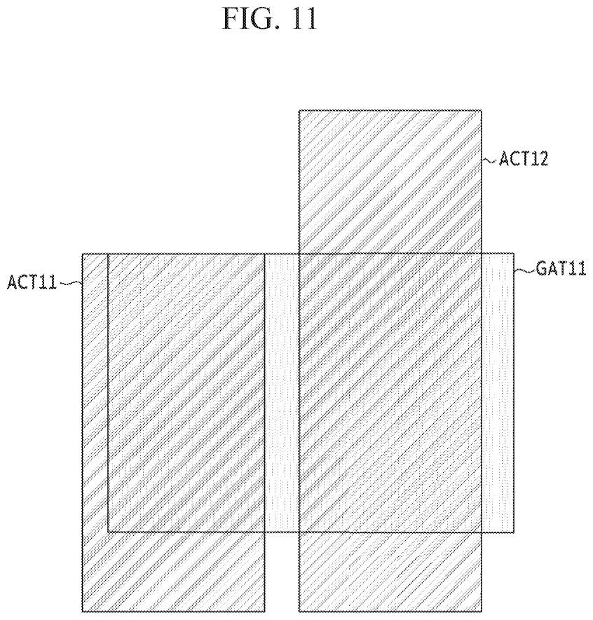

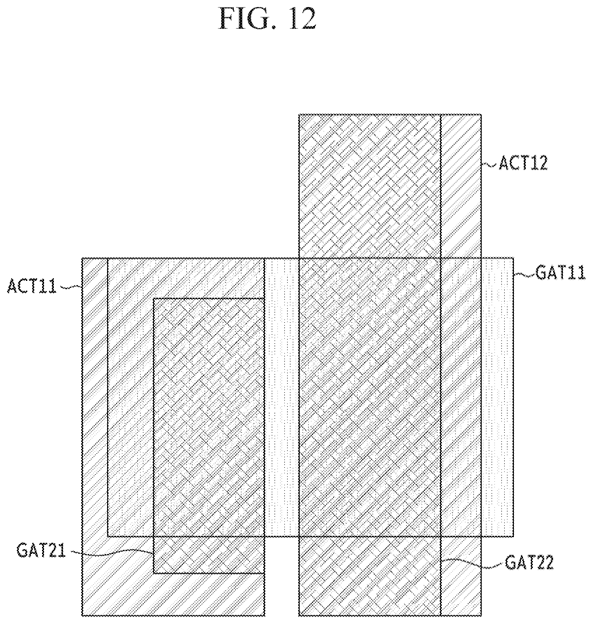

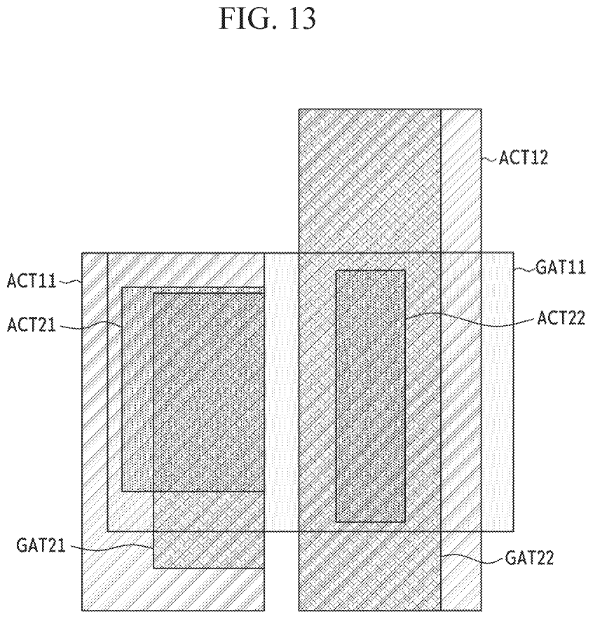

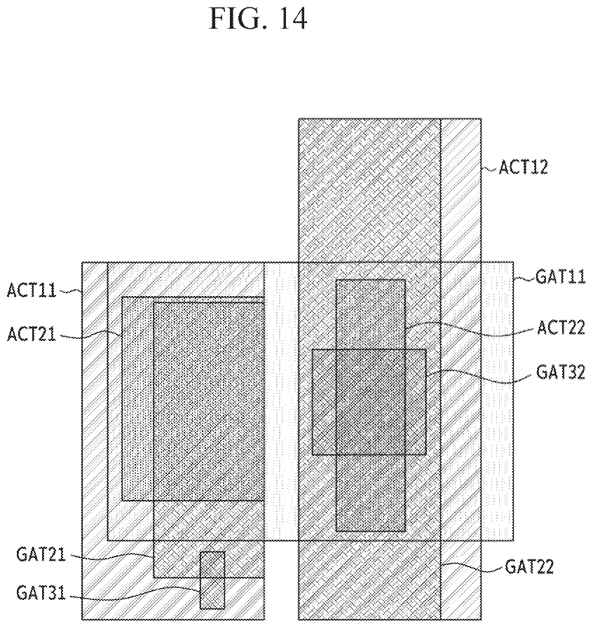

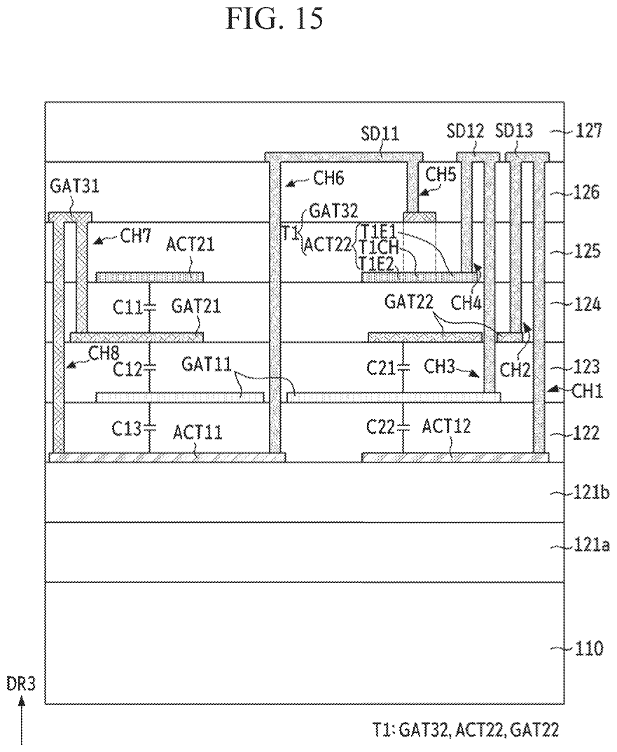

FIG. 8 is a modified circuit diagram illustrating portion K of FIG. 7 in more detail. FIG. 9 is a schematic cross-sectional view illustrating a connection relationship between a pixel circuit and a light emitting element according to some embodiments of the present disclosure. FIG. 10 is a plan view illustrating a first semiconductor layer located in the display device according to some embodiments of the present disclosure. FIG. 11 is a plan view further illustrating a first gate metal layer located in the display device according to some embodiments of the present disclosure. FIG. 12 is a plan view further illustrating a second gate metal layer located in the display device according to some embodiments of the present disclosure. FIG. 13 is a plan view further illustrating a second semiconductor layer located in the display device according to some embodiments of the present disclosure. FIG. 14 is a plan view further illustrating a third gate metal layer located in the display device according to some embodiments of the present disclosure. FIG. 15 is a cross-sectional view illustrating the display device according to some embodiments of the present disclosure.

Referring to FIG. 9, as described above, the pixel circuit may include a plurality of transistors T1 to T6, and a transistor T illustrated in FIG. 9 may correspond to any one of the plurality of transistors described above.

The transistor T includes electrodes TE1, TE2, and TG of the transistor T and a channel portion TCH of the transistor T, and the electrodes TE1, TE2, and TG of the transistor T may include a first electrode TE1 of the transistor T, a second electrode TE2 of the transistor T, and a gate electrode TG of the transistor T. The channel portion TCH of the transistor T may be located between the first electrode TE1 of the transistor T and the second electrode TE2 of the transistor T, and may overlap the gate electrode TG of the transistor T in the third direction. When the transistor T is the first transistor, the transistor T may further include the back gate electrode the back gate voltage.

The display device according to some embodiments of the present disclosure may include a substrate 110 and a plurality of insulating films. The plurality of insulating films may include a first buffer film 121a, a second buffer film 121b, a first gate insulating film 122, a second gate insulating film 123, a first interlayer insulating film 124, a third gate insulating film 125, a second interlayer insulating film 126, and the like, but embodiments of the present disclosure are not limited thereto. The display device may further include a planarization film 127 and 128 located on the plurality of insulating films. The planarization film may be formed as multiple layers including a first planarization film 127 and a second planarization film 128, but embodiments of the present disclosure are not limited thereto.

The first buffer film 121a may be formed on the substrate 110 of the display device according to some embodiments, and a bottom metal layer BML may be formed on the first buffer film 121a. A first semiconductor layer ACT1 may be formed on the second buffer film 121b. A first gate metal layer GAT1 may be formed on the first gate insulating film 122. A second gate metal layer GAT2 may be formed on the second gate insulating film 123. A second semiconductor layer ACT2 may be formed on the first interlayer insulating film 124. A third gate metal layer GAT3 may be formed on the third gate insulating film 125. A first connection metal layer SD1 may be formed on the second interlayer insulating film 126. A second connection metal layer SD2 may be located on the first planarization film 127.

An element layer may be formed on the second planarization film 128, and the element layer may include a light emitting element LE and a bank BK. The light emitting element LE may include an anode electrode AND, a light emitting layer EL, and a cathode electrode CAT, and the bank BK may cover at least portions of one end and/or the other end of the anode electrode AND and define an emission area.

The substrate 110 may be made of an insulating material such as a polymer resin or glass. The substrate 110 may include a glass material. The substrate 110 may include polyimide. In this case, the substrate 110 may be a flexible substrate that may be bent, folded, and rolled.

The first buffer film 121a located on the substrate 110 may be formed as a silicon nitride layer, a silicon oxynitride layer, a silicon oxide layer, a titanium oxide layer, or an aluminum oxide layer.

The bottom metal layer BML located on the first buffer film 121a may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The second buffer film 121b covering the bottom metal layer BML may be formed as a silicon nitride layer, a silicon oxynitride layer, a silicon oxide layer, a titanium oxide layer, or an aluminum oxide layer. The second buffer film 121b may include an inorganic film capable of preventing or reducing permeation of contaminants such as air or moisture. The second buffer film 121b may include a plurality of inorganic films that are alternately stacked.

The first semiconductor layer ACT1 located on the second buffer film 121b may include a silicon semiconductor such as polycrystalline silicon, single crystal silicon, low temperature polycrystalline silicon, or amorphous silicon. An electrode may be formed when the first semiconductor layer ACT1 is doped with ions or impurities. The first semiconductor layer ACT1 doped with the ions or the impurities may have conductivity.

The first gate insulating film 122 covering the first semiconductor layer ACT1 may be formed as an inorganic film such as a silicon nitride layer, a silicon oxynitride layer, a silicon oxide layer, a titanium oxide layer, or an aluminum oxide layer.

The first gate metal layer GAT1 located on the first gate insulating film 122 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The second gate insulating film 123 covering the first gate metal layer GAT1 may be formed as an inorganic film such as a silicon nitride layer, a silicon oxynitride layer, a silicon oxide layer, a titanium oxide layer, or an aluminum oxide layer.

The second gate metal layer GAT2 located on the second gate insulating film 123 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The first interlayer insulating film 124 covering the second gate metal layer GAT2 may be formed as an inorganic film such as a silicon nitride layer, a silicon oxynitride layer, a silicon oxide layer, a titanium oxide layer, or an aluminum oxide layer.

The second semiconductor layer ACT2 located on the first interlayer insulating film 124 may include an oxide semiconductor. An electrode may be formed when the second semiconductor layer ACT2 is doped with ions or impurities. The second semiconductor layer ACT2 doped with the ions or the impurities may have conductivity.

The third gate insulating film 125 covering the second semiconductor layer ACT2 may be formed as an inorganic film such as a silicon nitride layer, a silicon oxynitride layer, a silicon oxide layer, a titanium oxide layer, or an aluminum oxide layer.

The third gate metal layer GAT3 located on the third gate insulating film 125 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The second interlayer insulating film 126 covering the third gate metal layer GAT3 may be formed as an inorganic film such as a silicon nitride layer, a silicon oxynitride layer, a silicon oxide layer, a titanium oxide layer, or an aluminum oxide layer.

The first connection metal layer SD1 located on the second interlayer insulating film 126 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The first planarization film 127 covering the first connection metal layer SD1 may be formed as an organic film made of an acrylic resin, an epoxy resin, a phenolic resin, a polyamide resin, a polyimide resin, or the like.

The second connection metal layer SD2 located on the first planarization film 127 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The second planarization film 128 covering the second connection metal layer SD2 may be formed as an organic film made of an acrylic resin, an epoxy resin, a phenolic resin, a polyamide resin, a polyimide resin, or the like.

The light emitting element LE including the anode electrode AND, the light emitting layer EL, and the cathode electrode CAT may be located on the second planarization film 128. The anode electrode AND may be electrically connected or in contact with anode connection electrodes ANCE1 and ANCE2 through anode contact holes ANCH1 and ANCH2 respectively formed in the first planarization film 127 and the second planarization film 128. According to some embodiments, a first anode connection electrode ANCE1 and a second anode connection electrode ANCE2 may be configured as one anode connection electrode, and in this case, the first planarization film 127 and the second planarization film 128 may also be configured as one planarization film.

For example, the transistor T may include an oxide semiconductor. Accordingly, the channel portion TCH of the transistor T located between the first electrode TE1 of the transistor T and the second electrode TE2 of the transistor T may include an oxide semiconductor. The gate electrode TG of the transistor T may overlap the channel portion TCH of the transistor T in the third direction DR3. The first electrode TE1 of the transistor T may be electrically connected to the first anode connection electrode ANCE1 through a contact hole CH. However, embodiments of the present disclosure are not limited to that illustrated in FIG. 9. The number of electrodes or the number of contact holes CH connected to the light emitting element LE may be changed according to some embodiments. Those illustrated in FIG. 9 represent conceptual portions. A practitioner may derive various electrical connection relationships by utilizing a plurality of metal layers BML, GAT1, GAT2, GAT3, SD1, and SD2, doped semiconductor layers ACT1 and ACT2, undoped semiconductor layers ACT1 and ACT2, and corresponding gate metal layers GAT1 and GAT3, the contact hole CH, and the like.

In a top emission structure in which light is emitted toward the cathode electrode CAT based on the light emitting layer EL, the anode electrode AND may be made of a metal material having high reflectivity, such as a stacked structure (Ti/Al/Ti) of aluminum and titanium, a stacked structure (ITO/Al/ITO) of aluminum and indium tin oxide (ITO), an APC alloy, and a stacked structure (ITO/APC/ITO) of an APC alloy and ITO. The APC alloy is an alloy of silver (Ag), palladium (Pd), and copper (Cu).

The bank BK may partition the anode electrode AND on the second planarization film 128 in order to serve to define an emission area EA. The emission area EA refers to an area where the anode electrode AND, the light emitting layer EL, and the cathode electrode CAT are sequentially stacked and holes from the anode electrode AND and electrons from the cathode electrode CAT combine with each other in the light emitting layer EL to emit light. The bank BK may cover an edge of the anode electrode AND. The bank BK may be formed as an organic film made of an acrylic resin, an epoxy resin, a phenolic resin, a polyamide resin, a polyimide resin, or the like.

The light emitting layer EL may be formed on the anode electrode AND. The light emitting layer EL may include an organic material to emit light of a selected color. For example, the light emitting layer EL may include a hole transporting layer, an organic material layer, and an electron transporting layer.

The cathode electrode CAT may be formed on the light emitting layer EL. The cathode electrode CAT may cover the light emitting layer EL. The cathode electrode CAT may be a common layer formed in common in all emission areas EA including the emission area EA illustrated in FIG. 9. A capping layer may be formed on the cathode electrode CAT.

In the top emission structure, the cathode electrode CAT may be made of transparent conductive oxide (TCO) such as ITO or indium zinc oxide (IZO) capable of transmitting light or a semi-transmissive conductive material such as magnesium (Mg), silver (Ag), or an alloy of magnesium (Mg) and silver (Ag). When the cathode electrode CAT is made of the semi-transmissive conductive material, light emission efficiency may be increased by a micro cavity.

An encapsulation layer TFEL may be located on the cathode electrode CAT. The encapsulation layer TFEL may include at least one inorganic film in order to prevent or reduce contaminants such as oxygen or moisture permeating into the light emitting element LE. In addition, the encapsulation layer TFEL may include at least one organic film in order to protect the light emitting element LE from foreign substances such as dust. For example, the encapsulation layer TFEL may include a plurality of inorganic films and a single organic film, but embodiments of the present disclosure are not limited thereto. The inorganic film may be formed as multiple films in which one or more inorganic films of a silicon nitride layer, a silicon oxynitride layer, a silicon oxide layer, a titanium oxide layer, and an aluminum oxide layer are alternately stacked. The organic film may be made of an acrylic resin, an epoxy resin, a phenolic resin, a polyamide resin, a polyimide resin, or the like.

A filling layer, a sealant, and an encapsulation substrate may be formed instead of the encapsulation layer TFEL. In this case, the encapsulation substrate may be an insulating substrate including an insulating material such as glass or plastic. The filling layer may be an air layer in a vacuum state, but is not limited thereto. The sealant may be located in the non-display area of the display panel so as to surround the display area.

Referring to FIGS. 8 to 15, the pixel circuit according to some embodiments of the present disclosure may include a first group capacitor C11, C12, and C13, a second group capacitor C21 and C22, a first transistor T1, and the like. In the modified circuit diagram, in addition to an electrical connection relationship of the circuit diagram, connection relationships of electrodes, lines, and the like, and contact holes that may appear in a cross-sectional view are illustrated. The pixel circuit including the first group capacitor C11, C12, and C13, the second group capacitor C21 and C22, the first transistor T1, and the like, as illustrated in FIG. 8 may include a first contact hole CH1, a second contact hole CH2, a third contact hole CH3, a fourth contact hole CH4, a fifth contact hole CH5, a sixth contact hole CH6, a seventh contact hole CH7, and an eighth contact hole CH8.

The first group capacitor C11, C12, and C13 may include a first capacitor C11, a second capacitor C12, and a third capacitor C13 that are connected to each other in parallel. The second group capacitor C21 and C22 may include a fourth capacitor C21 and a fifth capacitor C22 that are connected to each other in parallel. Each of the first capacitor C11, the second capacitor C12, the third capacitor C13, the fourth capacitor C21, and the fifth capacitor C22 may include a first electrode and a second electrode overlapping each other in the third direction DR3.

The plurality of capacitors may share electrodes with each other. A second electrode GAT21 of the first capacitor C11 may be the same as a second electrode GAT21 of the second capacitor C12. A first electrode GAT11 of the second capacitor C12 may be the same as a first electrode GAT11 of the third capacitor C13. The first electrode GAT11 of the second capacitor C12 may be the same as a first electrode GAT11 of the fourth capacitor C21. The first electrode GAT11 of the fourth capacitor C21 may be the same as a first electrode GAT11 of the fifth capacitor C22.

The first semiconductor layer may include a second electrode ACT11 of the third capacitor C13 and a second electrode ACT12 of the fifth capacitor C22 (see FIGS. 8, 10, and 15).

The first gate metal layer may include the first electrode GAT11 of the second capacitor C12. Because the first electrode GAT11 of the second capacitor C12 is the same as the first electrode GAT11 of the third capacitor C13, the first gate metal layer may include the first electrode GAT11 of the third capacitor C13. In addition, because the first electrode GAT11 of the second capacitor C12 is the same as the first electrode GAT11 of the fourth capacitor C21, the first gate metal layer may include the first electrode GAT11 of the fourth capacitor C21. In addition, because the first electrode GAT11 of the fourth capacitor C21 is the same as the first electrode GAT11 of the fifth capacitor C22, the first gate metal layer may include the first electrode GAT11 of the fifth capacitor C22. The first electrode GAT11 of the second capacitor C12 may function as the first electrode GAT11 of the second capacitor C12 or the first electrode GAT11 of the third capacitor C13 in a partial area, and may function as the first electrode GAT11 of the fourth capacitor C21 or the first electrode GAT11 of the fifth capacitor C22 in the other area (see FIGS. 8, 11, and 15).

The second gate metal layer may include the second electrode GAT21 of the first capacitor C11 and a second electrode GAT22 of the fourth capacitor C21. Because the second electrode GAT21 of the first capacitor C11 is the same as the second electrode GAT21 of the second capacitor C12, the second gate metal layer may include the second electrode GAT21 of the second capacitor C12 and the second electrode GAT22 of the fourth capacitor C21. The second electrode GAT22 of the fourth capacitor C21 may be the same as a back gate electrode GAT22 of the first transistor T1. Because the second electrode GAT22 of the fourth capacitor C21 is the same as the back gate electrode GAT22 of the first transistor T1, the second gate metal layer may include the back gate electrode GAT22 of the first transistor T1 (see FIGS. 8, 12, and 15).

The second semiconductor layer may include a first electrode ACT21 of the first capacitor C11, a first electrode T1 E1 of the first transistor T1, a second electrode T1E2 of the first transistor T1, and a channel portion T1CH (or a first channel portion) of the first transistor T1 located between the first electrode T1 E1 of the first transistor T1 and the second electrode T1E2 of the first transistor T1 (see FIGS. 8, 13, and 15).

The third gate metal layer may include a third connection electrode GAT31 and a gate electrode GAT32 of the first transistor T1 (see FIGS. 8, 14, and 15).

The first connection metal layer may include a third driving voltage line SD13, a first connection electrode SD12, and a second connection electrode SD11 (see FIGS. 8 and 15).

Referring to FIGS. 8 and 15, the first transistor T1 may include the first electrode T1 E1 of the first transistor T1, the second electrode T1E2 of the first transistor T1, the channel portion T1CH of the first transistor T1, and the gate electrode GAT32 of the first transistor T1. The channel portion T1CH of the first transistor T1 may be located at the second semiconductor layer including the oxide semiconductor. The channel portion T1CH of the first transistor T1 may overlap the gate electrode GAT32 of the first transistor T1.

In the display device according to some embodiments, in order to variably apply the back gate voltage TUN of the first transistor T1 according to a luminance/grayscale, the second group capacitor C21 and C22 may be formed in an area that overlaps the first transistor T1 in the third direction DR3. The second group capacitor C21 and C22 may be located between a node to which the third driving voltage TUN is applied and a node to which a potential of the first electrode T1 E1 of the first transistor T1 is applied. The second group capacitor C21 and C22 may include the fourth capacitor C21 and the fifth capacitor C22.

The first transistor T1 may further include the back gate electrode GAT22 to which the third driving voltage TUN is applied. The back gate electrode GAT22 may overlap the channel portion T1CH of the first transistor T1 in the third direction DR3. The third driving voltage line SD13 to which the third driving voltage TUN is applied may be electrically connected to the back gate electrode GAT22 through the second contact hole CH2. The back gate electrode GAT22 may be the same as the second electrode GAT22 of the fourth capacitor C21. The first electrode T1 E1 of the first transistor T1 may be electrically connected to the first connection electrode SD12 through the fourth contact hole CH4. The first connection electrode SD12 may be electrically connected to the first electrode GAT11 of the fourth capacitor C21 through the third contact hole CH3. The back gate electrode GAT22 may form the fourth capacitor C21 with the first electrode GAT11 of the fourth capacitor C21.

The third driving voltage line SD13 may be electrically connected to the second electrode ACT12 of the fifth capacitor C22 through the first contact hole CH1. The first electrode GAT11 of the fourth capacitor C21 (or the first electrode GAT11 of the fifth capacitor C22) electrically connected to the first electrode T1 E1 of the first transistor T1 through the fourth contact hole CH4 and the third contact hole CH3 may form the fifth capacitor C22 with the second electrode ACT12 of the fifth capacitor C22 electrically connected to the third driving voltage line SD13 through the first contact hole CH1.

In the display device according to some embodiments, the second group capacitor C21 and C22 is formed in the area that overlaps the first transistor T1 in the third direction DR3, and accordingly, the first group capacitor C11, C12, and C13 may be located in an area that does not overlap the first transistor T1 in the third direction DR3 For example, the first group capacitor C11, C12, and C13 may not overlap the second group capacitor C21 and C22 in the third direction DR3. The first group capacitor C11, C12, and C13 may be misaligned with the second group capacitor C21 and C22 in the third direction DR3. The first group capacitor C11, C12, and C13 may be located between the node to which the potential of the first electrode T1 E1 of the first transistor T1 is applied and a node to which a potential of the gate electrode GAT32 of the first transistor T1 is applied. The first group capacitor C11, C12, and C13 may include the first capacitor C11, the second capacitor C12, and the third capacitor C13.

The gate electrode GAT32 of the first transistor T1 may be electrically connected to the second connection electrode SD11 through the fifth contact hole CH5. The second connection electrode SD11 may be electrically connected to the second electrode ACT11 of the third capacitor C13 through the sixth contact hole CH6. The second electrode ACT11 of the third capacitor C13 may be electrically connected to the third connection electrode GAT31 through the eighth contact hole CH8. The third connection electrode GAT31 may be electrically connected to the second electrode GAT21 of the first capacitor C11 (or the second electrode GAT21 of the second capacitor C12) through the seventh contact hole CH7. The first electrode ACT21 of the first capacitor C11 may form the first capacitor C11 with the second electrode GAT21 of the first capacitor C11.

The second electrode GAT21 of the first capacitor C11 may be the same as the second electrode GAT21 of the second capacitor C12. In addition, the first electrode GAT11 of the fourth capacitor C21 may be the same as the first electrode GAT11 of the second capacitor C12 (or the first electrode GAT11 of the third capacitor C13). A partial area of the first electrode GAT11 of the second capacitor C12 may form the second capacitor C12 and the third capacitor C13, and the other area of the first electrode GAT11 of the second capacitor C12 may form the fourth capacitor C21 and the fifth capacitor C22. The first electrode GAT11 of the second capacitor C12 may form the second capacitor C12 with the second electrode GAT21 of the first capacitor C11 (or the second electrode GAT21 of the second capacitor C12).

Because the first electrode GAT11 of the second capacitor C12 is the same as the first electrode GAT11 of the third capacitor C13, the first electrode GAT11 of the second capacitor C12 (or the first electrode GAT11 of the third capacitor C13) may form the third capacitor C13 with the second electrode ACT11 of the third capacitor C13.

According to some embodiments, upper and lower relationships between the respective electrodes may be derived with reference to the above-described description, and some overlapping description thereof may be omitted.

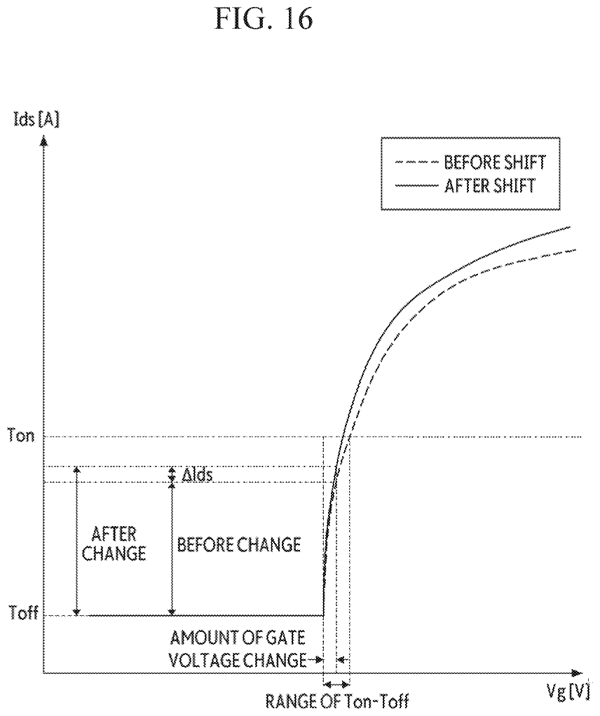

FIG. 16 is graphs illustrating a driving current curve of a first transistor according to some embodiments of the present disclosure. FIG. 17 is a table for describing the display device according to some embodiments of the present disclosure.

Referring to FIGS. 16 and 17, as described above, the display device according to some embodiments may provide a means for solving a problem that luminance sensitivity at a low grayscale decreases as a brightness value decreases.

Referring to the table of FIG. 17, a control signal may include a first brightness value DBV1, a second brightness value DBV2 greater than the first brightness value DBV1, a third brightness value DBV3 greater than the second brightness value DBV2, or a fourth brightness value DBV4 greater than the third brightness value DBV3. A description will be provided assuming each brightness value is a maximum brightness value, but embodiments of the present disclosure are not limited thereto.

When each brightness value is assumed as the maximum brightness value, for example, a brightness value at a 255-th grayscale (255G) value may be a maximum brightness value.

The fourth brightness value DBV4 and the third brightness value DBV3 correspond to relatively high brightness values, and the second brightness value DBV2 and the first brightness value DBV1 correspond to relatively low brightness values.

The third driving voltage TUN may be input as the back gate voltage of the first transistor. For example, a first sub-driving voltage TUN1, a second sub-driving voltage TUN2 greater than the first sub-driving voltage TUN1, or a third sub-driving voltage TUN3 greater than the second sub-driving voltage TUN2 may be input as third driving voltage TUN. As described above, the third driving voltage TUN input to the display device according to some embodiments may be different depending on the luminance/grayscale.

For example, regardless of the maximum brightness value, the first sub-driving voltage TUN1 may be input as the third driving voltage TUN.

When a control signal including the fourth brightness value DBV4 is input, a brightness value A4 corresponding to a third grayscale (3G) value and a brightness value B4 corresponding to an eleventh grayscale (11G) value are derived. Because the maximum brightness value corresponds to the 255-th grayscale (255G) value, the third grayscale (3G) value and the eleventh grayscale (11G) value may correspond to a relatively low-grayscale region. A change amount (C4) in brightness value according to a change amount (8G) in grayscale value in the low-grayscale region may correspond to a gradient (C4/8G) of a driving current curve in the low-grayscale region when the fourth brightness value DBV4 is input as the control signal.

When a control signal including the third brightness value DBV3 is input, a brightness value A3 corresponding to a third grayscale (3G) value and a brightness value B3 corresponding to an eleventh grayscale (11G) value are derived. Because the maximum brightness value corresponds to the 255-th grayscale (255G) value, the third grayscale (3G) value and the eleventh grayscale (11G) value may correspond to a relatively low-grayscale region. A change amount (C3) in brightness value according to a change amount (8G) in grayscale value in the low-grayscale region may correspond to a gradient (C3/8G) of a driving current curve in the low-grayscale region when the third brightness value DBV3 is input as the control signal.

When a control signal including the second brightness value DBV2 is input, a brightness value A2 corresponding to a third grayscale (3G) value and a brightness value B2 corresponding to an eleventh grayscale (11G) value are derived. Because the maximum brightness value corresponds to the 255-th grayscale (255G) value, the third grayscale (3G) value and the eleventh grayscale (11G) value may correspond to a relatively low-grayscale region. A change amount (C2) in brightness value according to a change amount (8G) in grayscale value in the low-grayscale region may correspond to a gradient (C2/8G) of a driving current curve in the low-grayscale region when the second brightness value DBV2 is input as the control signal.

When a control signal including the first brightness value DBV1 is input, a brightness value A1 corresponding to a third grayscale (3G) value and a brightness value B1 corresponding to an eleventh grayscale (11G) value are derived. Because the maximum brightness value corresponds to the 255-th grayscale (255G) value, the third grayscale (3G) value and the eleventh grayscale (11G) value may correspond to a relatively low-grayscale region. A change amount (C1) in brightness value according to a change amount (8G) in grayscale value in the low-grayscale region may correspond to a gradient (C1/8G) of a driving current curve in the low-grayscale region when the first brightness value DBV1 is input as the control signal.

When the first sub-driving voltage TUN1 is input as the third driving voltage TUN regardless of the maximum brightness value, the gradient (C1/8G) of the driving current curve in the low-grayscale region when the first brightness value DBV1 is input as the control signal and the gradient (C2/8G) of the driving current curve in the low-grayscale region when the second brightness value DBV2 is input as the control signal may be smaller than the gradient (C3/8G) of the driving current curve in the low-grayscale region when the third brightness value DBV3 is input as the control signal or the gradient (C4/8G) of the driving current curve in the low-grayscale region when the fourth brightness value DBV4 is input as the control signal.

A small gradient of the driving current curve means that a change amount in driving current (a change amount in luminance or a change amount in brightness value) according to a change amount in grayscale value (change amount in input data voltage) is small, which means that luminance sensitivity to a change amount in voltage is small in the low-grayscale region.

In order to solve a problem that luminance sensitivity according to a change amount in voltage in the low-grayscale region is small, the display device according to some embodiments of the present disclosure may apply a different third driving voltage TUN when the brightness value included in the input control signal is changed. For example, when the first brightness value DBV1 is input as the maximum brightness value, the third sub-driving voltage TUN3 may be input, and when the second brightness value DBV2 is input as the maximum brightness value, the second sub-driving voltage TUN2 may be input.

The first brightness value DBV1 may be input as the maximum brightness value, and the third sub-driving voltage TUN3 may be applied as the third driving voltage TUN.

When a control signal including the first brightness value DBV1 is input, a brightness value A1′ corresponding to a third grayscale (3G) value and a brightness value B1′ corresponding to an eleventh grayscale (11G) value are derived. Because the maximum brightness value corresponds to the 255-th grayscale (255G) value, the third grayscale (3G) value and the eleventh grayscale (11G) value may correspond to a relatively low-grayscale region. A change amount (C1′) in brightness value according to a change amount (8G) in grayscale value in the low-grayscale region may correspond to a gradient (C1′/8G) of a driving current curve in the low-grayscale region when the first brightness value DBV1 is input as the control signal and the third sub-driving voltage TUN3 is input as the third driving voltage TUN.

According to some embodiments, the gradient (C1/8G) of the driving current curve in the low-grayscale region when the first brightness value DBV1 is input as the control signal and the first sub-driving voltage TUN1 is input as the third driving voltage TUN may be different from the gradient (C1′/8G) of the driving current curve in the low-grayscale region when the first brightness value DBV1 is input as the control signal and the third sub-driving voltage TUN3 is input as the third driving voltage TUN. Specifically, the gradient (C1′/8G) of the driving current curve in the low-grayscale region when the first brightness value DBV1 is input as the control signal and the third sub-driving voltage TUN3 is input as the third driving voltage TUN may be greater than the gradient (C1/8G) of the driving current curve in the low-grayscale region when the first brightness value DBV1 is input as the control signal and the first sub-driving voltage TUN1 is input as the third driving voltage TUN. Accordingly, the luminance sensitivity may be relatively improved.

The second brightness value DBV2 may be input as the maximum brightness value, and the second sub-driving voltage TUN2 may be applied as the third driving voltage TUN.

When a control signal including the second brightness value DBV2 is input, a brightness value A2′ corresponding to a third grayscale (3G) value and a brightness value B2′ corresponding to an eleventh grayscale (11G) value are derived. Because the maximum brightness value corresponds to the 255-th grayscale (255G) value, the third grayscale (3G) value and the eleventh grayscale (11G) value may correspond to a relatively low-grayscale region. A change amount (C2′) in brightness value according to a change amount (8G) in grayscale value in the low-grayscale region may correspond to a gradient (C2′/8G) of a driving current curve in the low-grayscale region when the second brightness value DBV2 is input as the control signal and the second sub-driving voltage TUN2 is input as the third driving voltage TUN.

According to some embodiments, the gradient (C2/8G) of the driving current curve in the low-grayscale region when the second brightness value DBV2 is input as the control signal and the first sub-driving voltage TUN1 is input as the third driving voltage TUN may be different from the gradient (C2′/8G) of the driving current curve in the low-grayscale region when the second brightness value DBV2 is input as the control signal and the second sub-driving voltage TUN2 is input as the third driving voltage TUN. Specifically, the gradient (C2′/8G) of the driving current curve in the low-grayscale region when the second brightness value DBV2 is input as the control signal and the second sub-driving voltage TUN2 is input as the third driving voltage TUN may be greater than the gradient (C2/8G) of the driving current curve in the low-grayscale region when the second brightness value DBV2 is input as the control signal and the first sub-driving voltage TUN1 is input as the third driving voltage TUN. Accordingly, the luminance sensitivity may be relatively improved.

According to some embodiments, as the brightness value input as the control signal decreases, the input third driving voltage TUN may increase. For example, the third driving voltage TUN applied when the second brightness value DBV2 is input as the control signal may be the second sub-driving voltage TUN2, and the third driving voltage TUN applied when the first brightness value DBV1 is input as the control signal may be the third sub-driving voltage TUN3 greater than the second sub-driving voltage TUN2.

Referring to the graphs of FIG. 16 together with the table of FIG. 17, a graph BEFORE SHIFT when the first sub-driving voltage TUN1 is applied as the third driving voltage TUN is different from a graph AFTER SHIFT when the second sub-driving voltage TUN2 or the third sub-driving voltage TUN3 is applied as the third driving voltage TUN. Specifically, in a range RANGE OF Ton-Toff where the first transistor is turned on/off, in relation to a change amount in driving current (Ids) (or a change amount in luminance) AFTER CHANGE and BEFORE CHANGE corresponding to a change amount in grayscale value AMOUNT OF GATE VOLTAGE CHANGE in the low-grayscale region, the graph AFTER SHIFT when the second sub-driving voltage TUN2 or the third sub-driving voltage TUN3 is applied as the third driving voltage TUN is greater than the graph BEFORE SHIFT when the first sub-driving voltage TUN1 is applied as the third driving voltage TUN (ΔIds). The change amount in grayscale value AMOUNT OF GATE VOLTAGE CHANGE in the low-grayscale region may correspond to a difference between the third grayscale (3G) value and the eleventh grayscale (11G) value described above. In addition, in the change amount in grayscale value, a “BEFORE CHANGE” portion may correspond to C1 or C2, and an “AFTER CHANGE” portion may correspond to C1′ or C2′.

According to the present disclosure, the third driving voltage TUN applied as the back gate voltage to the first transistor in the low-grayscale region is a constant voltage, but may be variably applied according to the brightness value in order to relatively improve the luminance sensitivity in the low-grayscale region. Accordingly, display quality of the display device may be relatively improved.

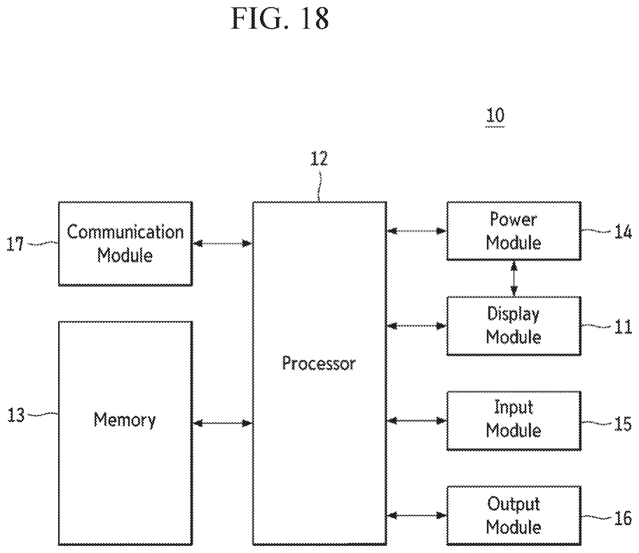

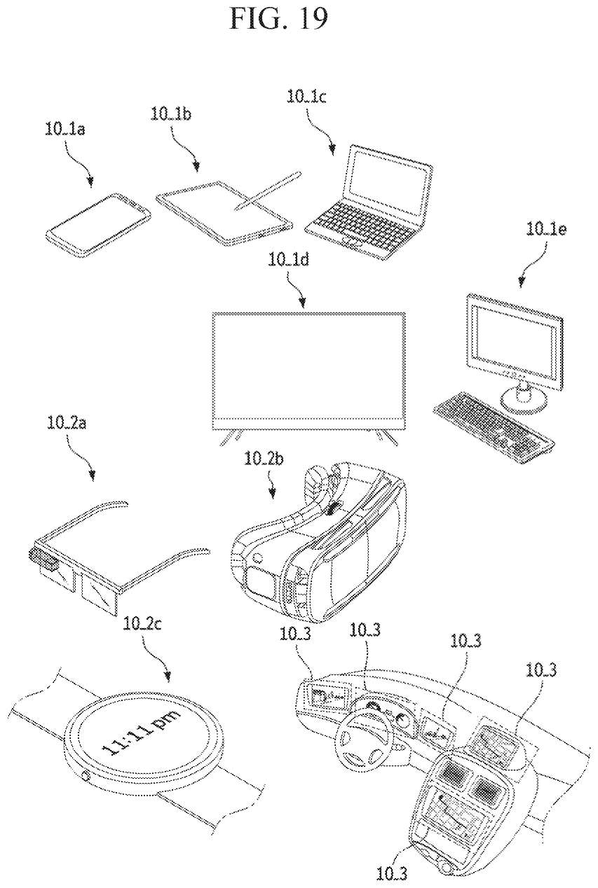

FIG. 18 is a block diagram of an electronic device according to some embodiments of the present disclosure. FIG. 19 is schematic views of electronic devices according to various embodiments of the present disclosure.

Referring to FIG. 18, an electronic device 10 according to some embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information necessary for an operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device. The power module 14 may include a power conversion module. The power conversion module may convert power supplied by the power supply module to generate power necessary for an operation of the electronic device 10.

At least one of the respective components of the above-described electronic device 10 may be included in the display device according to the above-described embodiments. In addition, some of individual modules functionally included in one module may be included in the display device, and the others of the individual modules may be provided separately from the display device. For example, the display device may include the display module 11, and the processor 12, the memory 13, and the power module 14 may be provided in the form of other devices within the electronic device rather than the display device.

Referring to FIG. 19, various electronic devices to which the display devices according to embodiments of the present disclosure are applied may include not only image display electronic devices such as a smartphone 10_1a, a tablet PC 10_1b, a laptop computer 10_1c, a television (TV) 10_1d, and a monitor 10_1e for a desktop computer. Furthermore, the various electronic devices to which the display devices according to embodiments of the present disclosure are applied may include wearable electronic devices including display modules, such as a smart glasses 10_2a, a head mounted display 10_2b, and a smart watch 10_2c, and vehicle electronic devices 10_3 including display modules, such as a center information display (CID) located on an instrument board, a center fascia, or a dashboard of a vehicle and a room mirror display.

Although aspects of some embodiments of the present disclosure have been described above with reference to the accompanying drawings, it will be understood by those having ordinary skill in the technical field to which the disclosure belongs that the disclosure may be practiced in other specific forms without altering the technical idea or essential features of the disclosure. It should therefore be understood that the embodiments described above are examples in all respects and are not intended to be limiting.

What is claimed is:

1. A display device comprising:
a first transistor including a first electrode, a second electrode, a first channel portion between the first electrode and the second electrode, a gate electrode overlapping the first channel portion, and a back gate electrode overlapping the first channel portion;
a light emitting element including an anode electrode, a cathode electrode, and a light emitting layer between the anode electrode and the cathode electrode;
a fifth transistor including a first electrode, a second electrode, and a fifth channel portion between the first electrode and the second electrode;
a first driving voltage line configured to transmit a first driving voltage; and
a third driving voltage line configured to transmit a third driving voltage,
wherein the first electrode of the fifth transistor is electrically connected to the second electrode of the first transistor,
the first driving voltage line is electrically connected to the second electrode of the fifth transistor,
a second driving voltage is configured to be transmitted to the cathode electrode, and
the third driving voltage line is electrically connected to the back gate electrode.

2. The display device of claim 1, wherein the first driving voltage, the second driving voltage, and the third driving voltage are constant voltages.

3. The display device of claim 1, further comprising:
a first group capacitor between the first electrode of the first transistor and the gate electrode of the first transistor; and
a second group capacitor between the first electrode of the first transistor and the third driving voltage line.

4. The display device of claim 3, wherein the first group capacitor includes a first capacitor, a second capacitor, and a third capacitor,
the second group capacitor includes a fourth capacitor and a fifth capacitor, and
each of the first capacitor, the second capacitor, the third capacitor, the fourth capacitor, and the fifth capacitor includes a first electrode and a second electrode.

5. The display device of claim 4, wherein the first electrode of the fourth capacitor is the same as the first electrode of the fifth capacitor.

6. The display device of claim 4, wherein the first electrode of the fifth capacitor is on the second electrode of the fifth capacitor, and
the second electrode of the fourth capacitor is on the first electrode of the fourth capacitor.

7. The display device of claim 4, wherein the second electrode of the fourth capacitor is the same as the back gate electrode, and
the first electrode of the first transistor and the second electrode of the first transistor are on the second electrode of the fourth capacitor.

8. The display device of claim 4, wherein the third driving voltage line is on the gate electrode of the first transistor.

9. The display device of claim 8, wherein the third driving voltage line is electrically connected to the second electrode of the fifth capacitor through a first contact hole, and
the third driving voltage line is electrically connected to the second electrode of the fourth capacitor through a second contact hole.

10. The display device of claim 9, wherein the first electrode of the first transistor is electrically connected to a first connection electrode through a fourth contact hole,
the first connection electrode is electrically connected to the first electrode of the fourth capacitor through a third contact hole, and
the first connection electrode is at a same layer as the third driving voltage line.

11. The display device of claim 4, wherein the first electrode of the fourth capacitor is the same as the first electrode of the second capacitor, and
the first electrode of the second capacitor is the same as the first electrode of the third capacitor.

12. The display device of claim 4, wherein the second electrode of the first capacitor is the same as the second electrode of the second capacitor.

13. The display device of claim 4, wherein the first electrode of the first capacitor is on the second electrode of the first capacitor, and
the first electrode of the first capacitor is at a same layer as the first electrode of the first transistor and the second electrode of the first transistor.

14. The display device of claim 4, wherein the second electrode of the second capacitor is on the first electrode of the second capacitor, and
the first electrode of the third capacitor is on the second electrode of the third capacitor.

15. The display device of claim 4, wherein the gate electrode of the first transistor is electrically connected to a second connection electrode through a fifth contact hole, and
the second connection electrode is electrically connected to the second electrode of the third capacitor through a sixth contact hole.

16. The display device of claim 4, wherein the second electrode of the third capacitor is electrically connected to a third connection electrode through an eighth contact hole, and
the third connection electrode is electrically connected to the second electrode of the first capacitor through a seventh contact hole.

17. An electronic device comprising:
a processor configured to provide an image signal and a control signal including a maximum brightness value;
a display module configured to receive the image signal and the control signal from the processor and to display an image; and
a power module configured to supply a power to the display module,
wherein the display module includes:
a first transistor including a first electrode, a second electrode, a first channel portion between the first electrode and the second electrode, a gate electrode overlapping the first channel portion, and a back gate electrode overlapping the first channel portion;
a light emitting element including an anode electrode, a cathode electrode, and a light emitting layer between the anode electrode and the cathode electrode;
a fifth transistor including a first electrode, a second electrode, and a fifth channel portion between the first electrode and the second electrode;
a first driving voltage line configured to transmit a first driving voltage; and
a third driving voltage line configured to transmit a third driving voltage,
the first electrode of the fifth transistor is electrically connected to the second electrode of the first transistor,
the first driving voltage line is electrically connected to the second electrode of the fifth transistor,
a second driving voltage is configured to be transmitted to the cathode electrode,
the third driving voltage line is electrically connected to the back gate electrode, and
the third driving voltage is configured to be changed depending on the maximum brightness value.

18. The electronic device of claim 17, wherein the third driving voltage is configured to increase as the maximum brightness value decreases.

19. The electronic device of claim 17, wherein in a driving current curve of the first transistor, a change amount in driving current is configured to increase as the third driving voltage increases.

20. The electronic device of claim 17, wherein the first driving voltage, the second driving voltage, and the third driving voltage are constant voltages.
